(19) United States
(12) Patent Application Publication
(10) Pub. No.: US 2014/0236527 A1
(43) Pub. Date: Aug. 21, 2014

(54) CLOUD BASED INFRASTRUCTURE FOR SUPPORTING PROTOCOL RECONFIGURATIONS IN PROTOCOL INDEPENDENT DEVICE TESTING SYSTEMS

(71) Applicant: ADVANTEST CORPORATION, (US)

(72) Inventors: Gerald Chan, Saratoga, CA (US); Erik Volkerink, Saratoga, CA (US)

(73) Assignee: ADVANTEST CORPORATION, Tokyo (JP)

(21) Appl. No.: 13/773,628

(22) Filed: Feb. 21, 2013

(51) Int. Cl. G01R 31/3183

(52) U.S. Cl. CPC G01R 31/318307
USPC 702/119

(57) ABSTRACT

A method for performing tests using automated test equipment (ATE) is presented. The method comprises obtaining a protocol selection for programming a programmable tester module using a graphical user interface (GUI). It further comprises accessing a configuration file associated with a protocol from a remote computer through a network. Subsequently, it comprises configuring a programmable tester module with a communication protocol for application to at least one device under test (DUT) using the configuration file. Finally, it comprises transmitting instructions to the programmable tester module for executing a program flow, wherein the program flow comprises a sequence of tests for testing the at least one DUT, and receiving results for those tests from the programmable tester module.

### CROSS-REFERENCE TO RELATED APPLICATIONS

### Related Applications

The present application is related to U.S. patent application Ser. No. ______, filed ______, entitled “TESTER WITH MIXED PROTOCOL ENGINE IN FPGA BLOCK,” naming John Frediani and Andrew Niemic as inventors, and having attorney docket number ATST-JP0089. That application is incorporated herein by reference in its entirety and for all purposes.

The present application is related to U.S. patent application Ser. No. ______, filed ______, entitled “A TESTER WITH ACCELERATION ON MEMORY AND ACCELERATION FOR AUTOMATIC PATTERN GENERATION WITHIN A FPGA BLOCK,” naming John Frediani as inventor, and having attorney docket number ATST-JP0091. That application is incorporated herein by reference in its entirety and for all purposes.

The present application is related to U.S. patent application Ser. No. ______, filed ______, entitled “A TEST ARCHITECTURE HAVING MULTIPLE FPGA BASED HARDWARE ACCELERATOR BLOCKS FOR TESTING MULTIPLE DUTS INDEPENDENTLY,” naming Gerald Chan, Andrew Niemic, Eric Kushnick, and Mei-Mei Sui as inventors, and having attorney docket number ATST-JP0090. That application is incorporated herein by reference in its entirety and for all purposes.

The present application is related to U.S. patent application Ser. No. ______, filed ______, entitled “GUI IMPLEMENTATIONS ON CENTRAL CONTROLLER COMPUTER SYSTEM FOR SUPPORTING PROTOCOL INDEPENDENT DEVICE TESTING,” naming Gerald Chan as inventor, and having attorney docket number ATST-JP0085. That application is incorporated herein by reference in its entirety and for all purposes.

The present application is related to U.S. patent application Ser. No. ______, filed ______, entitled “A TESTER WITH ACCELERATION FOR PACKET BUILDING WITHIN A FPGA BLOCK,” naming John Frediani as inventor, and having attorney docket number ATST-JP0088. That application is incorporated herein by reference in its entirety and for all purposes.

### FIELD OF THE INVENTION

The present disclosure relates generally to the field of automated test equipment and more specifically to techniques of controlling such equipment.

### BACKGROUND OF THE INVENTION

Automated test equipment (ATE) can be any testing assembly that performs a test on a semiconductor wafer or die, an integrated circuit (IC), a circuit board, or a packaged device such as a solid-state drive. ATE assemblies may be used to execute automated tests that quickly perform measurements and generate test results that can then be analyzed. An ATE assembly may be anything from a computer system coupled to a meter, to a complicated automated test assembly that may include a custom, dedicated computer control system and many different test instruments that are capable of automatically testing electronics parts and/or semiconductor wafer testing, such as system-on-chip (SOC) testing or integrated circuit testing. ATE systems both reduce the amount of time spent on testing devices to ensure that the device functions as designed and serve as a diagnostic tool to determine the presence of faulty components within a given device before it reaches the consumer.

When a typical ATE system tests a device (commonly referred to as a device under test or DUT), the ATE system applies stimuli (e.g. electrical signals) to the device and checks responses (e.g., currents and voltages) of the device. Typically, the end result of a test is either “pass” if the device successfully provides certain expected responses within pre-established tolerances, or “fail” if the device does not provide the expected responses within the pre-established tolerances. More sophistical ATE systems are capable of evaluating a failed device to potentially determine one or more causes of the failure.

It is common for an ATE system to include a computer that directs the operation of the ATE system. Typically, the computer runs one or more specialized software programs to provide (i) a test development environment and (ii) a device testing environment. In the test development environment, a user typically creates a test program, i.e., a software-based construct of one or more files that controls various portions of the ATE system. In the device testing environment, the user typically provides the ATE system with one or more devices for testing, and directs the ATE system to test each device in accordance with the test program. The user can test additional devices by simply providing the additional devices to the ATE system, and directing the ATE system to test the additional devices in accordance with the test program. Accordingly, the ATE system enables the user to test many devices in a consistent and automated manner based on the test program.

FIG. 1 is a schematic block diagram of a conventional automatic test equipment body 111 for testing certain typical DUTs e.g. a semiconductor memory device such as a DRAM, controlled by system controller 101 which communicates to the ATE apparatus 111 through a communication bus 102. The system controller 101 runs the software programs necessary to provide the test development environment and the device testing environment for running the user's tests.

The ATE body 111 includes hardware bus adapter sockets 108A-108N. Hardware bus adapter cards specific to a particular communication protocol e.g. PCIe, USB, SAS SATA etc. connect to the hardware bus adapter sockets 108A-108N provided on the ATE body and interface with the DUTs 109A-109N via cables specific to the respective protocol. The ATE body 111 also includes a tester processor 101 with an associated memory 105 to control the hardware components built into the ATE body 111 and to generate the commands and data necessary to communicate with the DUTs being tested through the hardware bus adapter cards. The tester processor 101 communicates with the hardware bus adapter cards over system bus 106.

The ATE body 111 tests the electrical functions of the DUTs 109A-109N connected to the ATE body 111 through hardware bus adapters plugged into the hardware bus adapter sockets of the ATE body. Accordingly, the tester processor 101 is programmed to communicate the test programs needed to be run to the DUTs using the protocol unique to the hardware bus adapters.

The test program run by the tester processor 101 may include a function test which involves writing input signals created by the algorithmic pattern generator 103 to the DUTs, reading out the written signals from the DUTs and using the comparator 104 to compare the output with the expected patterns. If the output does not match the input, the tester processor 101 will identify the DUT as being defective. For example, if the DUT is a memory device such as a DRAM, the test program will write data generated by the algorithmic pattern generator 103 to the DUT using a Write Operation, read data from the DRAM using a Read Operation and compare the expected bit pattern with the read pattern using the comparator 104. The tester processor 101 in typical systems comprises the functional blocks to generate the commands and test patterns used in testing the DUTs, such as the algorithmic pattern generator 103 and the comparator 104, programmed in software directly on the processor.

In conventional systems, the communication protocol used to communicate with the DUTs is fixed because the hardware bus adapter cards that plug into the ATE body 100 are single purpose devices that are designed to communicate in only one protocol and cannot be reprogrammed to communicate in a different protocol. For example, an ATE body configured to test PCIe devices will have hardware bus adapter cards plugged into the body that support only the PCIe protocol. In order to test DUTs supporting a different protocol, the user would ordinarily need to replace the PCIe hardware bus adapter cards with bus adapter cards supporting the other protocol. Unless the PCIe hardware bus adapter cards are physically substituted with cards supporting the other protocol, such a system can only test DUTs that support the PCIe protocol.

Further, the test application providing the test development environment on system controller 101 in conventional systems is designed to be sufficiently decoupled from the hardware so, among other things, it remained agnostic to the communication protocol used by the tester processor 101 to communicate with the DUTs. The intelligence built into the software program running on system controller 101 is limited simply to conveying instructions to the tester processor 101 and receiving results from the tester processor 101 to convey back to the user. Even the diagnostics tool built into the software is designed to be hardware independent. The software sends over the diagnostic function over to the tester processor 101, which has a corresponding driver that receives the instructions, processes the function and reports the results back to the software. This allows the test development environment residing on system controller 101 to be generic enough to where it allows the user to connect the system controller to different kinds of testers. However, it does not provide the user the control to perform hardware specific configurations. In order to reconfigure the tester apparatus 111, the user typically needs to physically reconfigure the hardware of apparatus 111.

Thus, on the test floor, critical time is consumed replacing hardware bus adapter cards and reconfiguring hardware manually when, for example, DUTs running a protocol different from the one that the existing adapter cards support need to be tested.

### BRIEF SUMMARY OF THE INVENTION

Accordingly, a need exists for a tester architecture that can address the problems with the systems described above. Further, what is needed is a test application for controlling an ATE body, wherein the communicative protocol engine is configurable so that the ATE body is not tied to any single protocol. Further, what is needed is a cloud based application through which the reconfigurable protocols used in the protocol engines can be accessed easily over a network. Also what is needed is a procedure for making decisions with respect to the ATE body based on the configured protocols. Using the beneficial aspects of the systems described, without their respective limitations, embodiments of the present invention provide a novel solution to address these problems.

Disclosed herein is a method for configuring a programmable tester module, wherein the tester module comprises a reconfigurable circuit for implementing one of a plurality of communication protocols. The method if user-friendly, enabling a user of normal skills to rapidly access and configure complex programmable tester modules with multiple configurations.

A method for performing tests using automated test equipment (ATE) is presented. The method comprises obtaining a protocol selection for programming a programmable tester module using a graphical user interface (GUI). It further comprises accessing a configuration file associated with a protocol from a remote computer through a network. Subsequently, it comprises configuring a programmable tester module with a communication protocol for application to at least one device under test (DUT) using the configuration file, wherein the programmable tester module is operable to be communicatively coupled to the at least one DUT. Finally, it comprises transmitting instructions to the programmable tester module for executing a program flow, wherein the program flow comprises a sequence of tests for testing the at least one DUT, and receiving results for those tests from the programmable tester module.

In another embodiment, a method for performing tests using automated test equipment (ATE) is disclosed. The method comprises obtaining a plurality of protocol selections for programming a plurality of programmable tester modules. It also comprises accessing configuration files associated with the plurality of protocol selections from a remote computer through a network. Further, it comprises configuring a plurality of programmable tester modules with communication protocols for application to a plurality of devices under test (DUTs) using the respective configuration files, wherein the plurality of programmable tester modules are communicatively coupled to the plurality of DUTs. The method subsequently comprises transmitting instructions to the plurality of programmable tester modules for executing tests on the plurality of DUTs. Finally, the method comprises receiving results from the plurality of programmable tester modules associated with running the tests on the plurality of DUTs.

In a different embodiment, a system for performing an automated test is disclosed. The system comprises a system controller communicatively coupled to at least one programmable tester module, wherein the system controller comprises a memory comprising a test application stored therein, a test interface to connect to the at least one programmable tester module and a processor coupled to the memory and the test interface. The processor is configured to operate in accordance with the test application to obtain a protocol selection for programming the at least one programmable tester module using a graphical user interface (GUI), access a configuration file associated with a protocol from a remote computer through a network and configure the at least one programmable tester module with a communication protocol for application to at least one device under test (DUT) using the configuration file, wherein the at least one programmable tester module is operable to be communicatively coupled to the at least one DUT. The processor is further configured to transmit instructions to the at least one programmable tester module for executing a program flow, wherein the program flow comprises a sequence of tests for testing the at least one DUT. Finally, the processor is configured to receive results from the programmable tester module associated with running the sequence of tests in the program flow on the at least one DUT.

In one embodiment, a method for performing tests using automated test equipment (ATE) is disclosed. The method comprises receiving a protocol selection for programming a programmable tester modules from a remote client computer. Further, it comprises accessing a configuration file associated with the protocol selection and transmitting the configuration file associated with the protocol selection to the remote client computer. Also, it comprises configuring a programmable tester module remotely with a communication protocol for application to at least one device under test (DUT) using the configuration file, wherein the programmable tester module is communicatively coupled to the at least one DUT. Subsequently, it comprises transmitting instructions to the programmable tester module for executing a program flow, wherein the program flow comprises a sequence of tests for testing the at least one DUT. Finally, it comprises receiving results from the remote client computer associated with running the sequence of tests in the program flow on the at least one DUT.

The following detailed description together with the accompanying drawings will provide a better understanding of the nature and advantages of the present invention.

### BRIEF DESCRIPTION OF THE DRAWINGS

Embodiments of the present invention are illustrated by way of example, and not by way of limitation, in the figures of the accompanying drawings and in which like reference numerals refer to similar elements.

FIG. 1 is a schematic block diagram of a conventional automated test system for testing a typical device under test (DUT);

FIG. 2A is a computer system on which embodiments of the automated test system of the present invention can be implemented in accordance with one embodiment of the present invention;

FIG. 2B is a block diagram of an example of a network architecture in which client systems and servers for an automated test system may be coupled to a network, according to embodiments of the present invention;

FIG. 3A is a high level schematic block diagram of the interconnections between the system controller, the site modules and the DUTs according to one embodiment of the present invention;

FIG. 3B is a detailed schematic block diagram of the site module and its interconnections with the system controller and the DUTs according to an embodiment of the present invention;

FIG. 3C is a detailed schematic block diagram of the instantiated FPGA tester block of FIG. 3A according to an embodiment of the present invention;

FIG. 4A is a schematic block diagram illustrating a typical hardware configuration for connecting the system controller with the tester slices and DUTs in the system in accordance with an embodiment of the present invention;

FIG. 4B is a schematic block diagram illustrating exemplary software components of the site modules and the system controller of the automated test system in accordance with one embodiment of the present invention;

FIG. 5 is a schematic block diagram illustrating the architecture of the test application in accordance with one embodiment of the present invention;

FIG. 6 illustrates an exemplary screen shot of a graphical user interface (GUI) for the test application illustrating the multiple tools available within the GUI in accordance with one embodiment of the present invention;

FIG. 7A illustrates a GUI-based implementation of a program flow tool within the test application in accordance with one embodiment of the present invention;

FIG. 7B illustrates a text-based implementation of a program flow tool within the test application in accordance with one embodiment of the present invention;

FIG. 8A illustrates a GUI-based implementation of a DUT configuration tool within the test application in accordance with one embodiment of the present invention;

FIG. 8B illustrates a text-based implementation of a DUT configuration tool within the test application in accordance with one embodiment of the present invention;

FIG. 9 illustrates the GUI for a shmoo tool within the test application in accordance with an embodiment of the present invention;

FIG. 10 illustrates an exemplary graphical representation of the layers of abstraction for an automated test system operating in accordance with one embodiment of the present invention;

FIG. 11 illustrates a flowchart of an exemplary computer implemented process for configuring a module comprising programmable devices with different protocols obtained over a network to test DUTs and receive test results for analysis in accordance with one embodiment of the present invention.

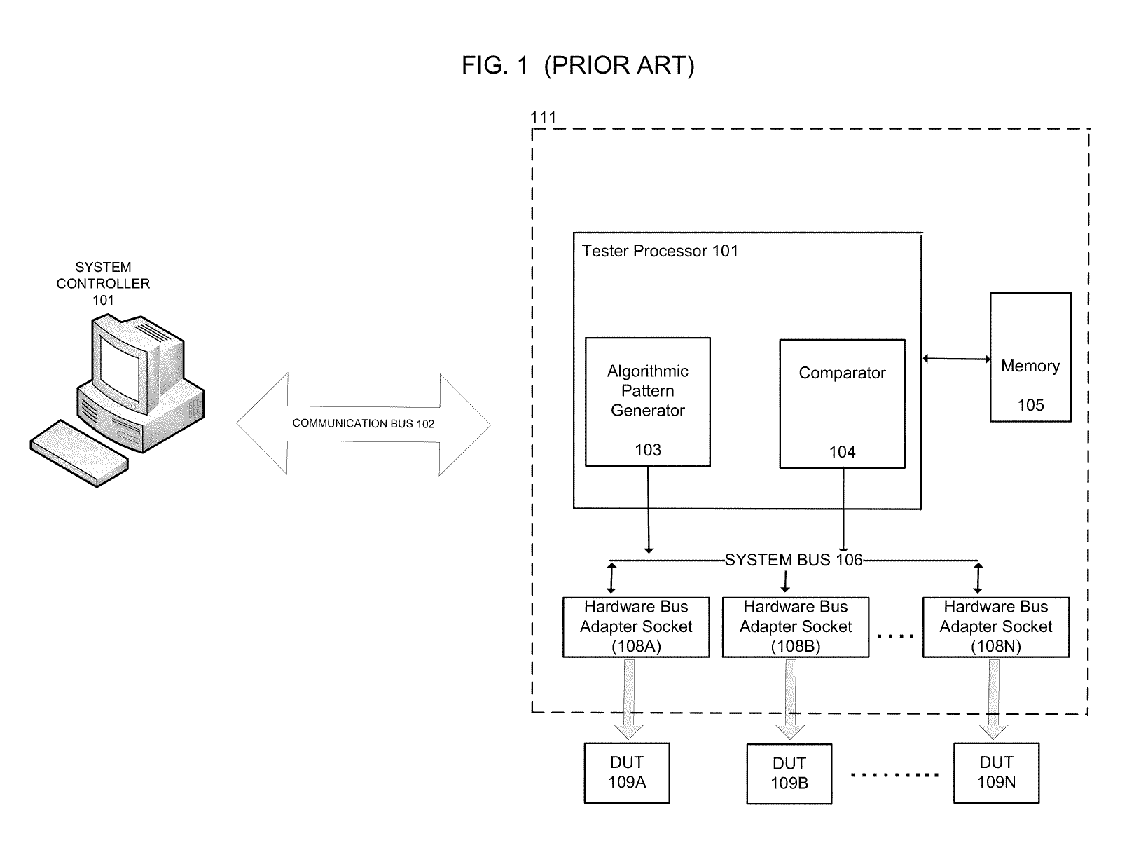

In the figures, elements having the same designation have the same or similar function.

### DETAILED DESCRIPTION OF THE INVENTION

Reference will now be made in detail to the various embodiments of the present disclosure, examples of which are illustrated in the accompanying drawings. While described in conjunction with these embodiments, it will be understood that they are not intended to limit the disclosure to these embodiments. On the contrary, the disclosure is intended to cover alternatives, modifications and equivalents, which may be included within the spirit and scope of the disclosure as defined by the appended claims. Furthermore, in the following detailed description of the present disclosure, numerous specific details are set forth in order to provide a thorough understanding of the present disclosure. However, it will be understood that the present disclosure may be practiced without these specific details. In other instances, well-known methods, procedures, components, and circuits have not been described in detail so as not to unnecessarily obscure aspects of the present disclosure.

Some portions of the detailed descriptions that follow are presented in terms of procedures, logic blocks, processing, and other symbolic representations of operations on data bits within a computer memory. These descriptions and representations are the means used by those skilled in the data processing arts to most effectively convey the substance of their work to others skilled in the art. In the present application, a procedure, logic block, process, or the like, is conceived to be a self-consistent sequence of steps or instructions leading to a desired result. The steps are those utilizing physical manipulations of physical quantities. Usually, although not necessarily, these quantities take the form of electrical or magnetic signals capable of being stored, transferred, combined, compared, and otherwise manipulated in a computer system. It has proven convenient at times, principally for reasons of common usage, to refer to these signals as transactions, bits, values, elements, symbols, characters, samples, pixels, or the like.

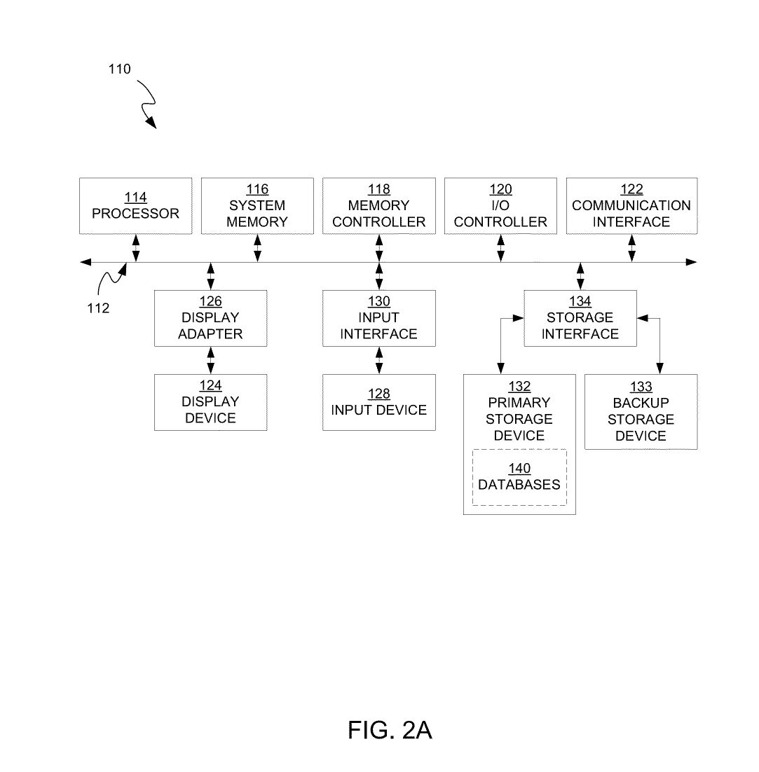

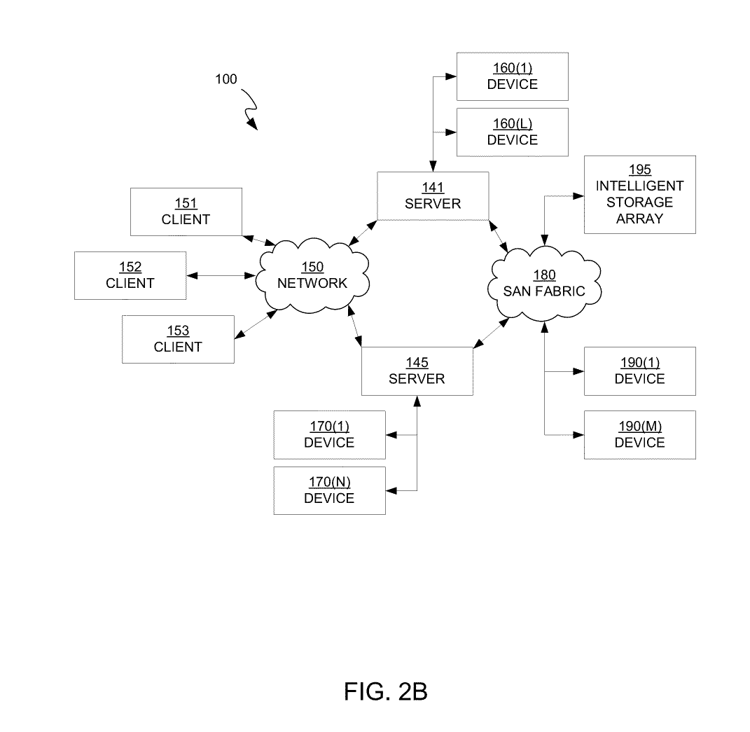

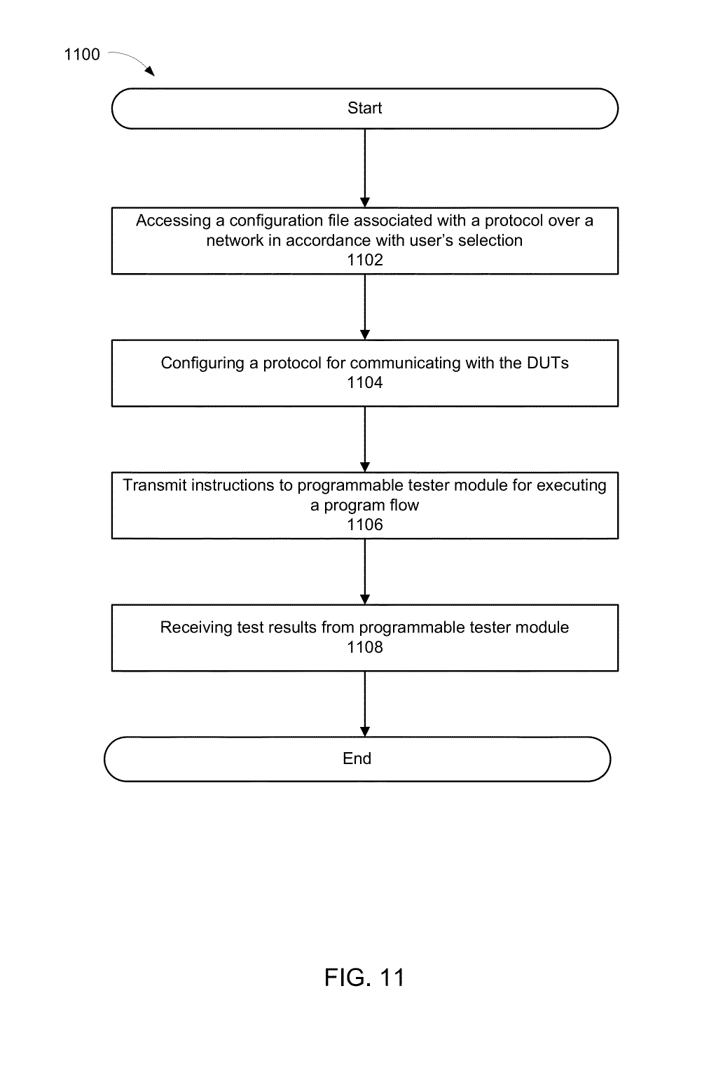

It should be borne in mind, however, that all of these and similar terms are to be associated with the appropriate physical quantities and are merely convenient labels applied to these quantities. Unless specifically stated otherwise as apparent from the following discussions, it is appreciated that throughout the present disclosure, discussions utilizing terms such as “obtaining,” “accessing,” “configuring,” “providing,” “executing,” “transmitting,” “implementing,” “programming,” “allocating,” “associating,” “setting,” “controlling,” “determining,” “identifying,” “caching,” “maintaining,” “comparing,” “removing,” “reading,” “writing,” or the like, refer to actions and processes (e.g., flowchart 1100 of FIG. 11) of a computer system or similar electronic computing device or processor (e.g., system 110 of FIG. 2A). The computer system or similar electronic computing device manipulates and transforms data represented as physical (electronic) quantities within the computer system memories, registers or other such information storage, transmission or display devices.

Embodiments described herein may be discussed in the general context of computer-executable instructions residing on some form of computer-readable storage medium, such as program modules, executed by one or more computers or other devices. By way of example, and not limitation, computer-readable storage media may comprise non-transitory computer-readable storage media and communication media; non-transitory computer-readable media include all computer-readable media except for a transitory, propagating signal. Generally, program modules include routines, programs, objects, components, data structures, etc., that perform particular tasks or implement particular abstract data types. The functionality of the program modules may be combined or distributed as desired in various embodiments.

Computer storage media includes volatile and nonvolatile, removable and non-removable media implemented in any method or technology for storage of information such as computer-readable instructions, data structures, program modules or other data. Computer storage media includes, but is not limited to, random access memory (RAM), read only memory (ROM), electrically erasable programmable ROM (EEPROM), flash memory or other memory technology, compact disk ROM (CD-ROM), digital versatile disks (DVDs) or other optical storage, magnetic cassettes, magnetic tape, magnetic disk storage or other magnetic storage devices, or any other medium that can be used to store the desired information and that can accessed to retrieve that information.

Communication media can embody computer-executable instructions, data structures, and program modules, and includes any information delivery media. By way of example, and not limitation, communication media includes wired media such as a wired network or direct-wired connection, and wireless media such as acoustic, radio frequency (RF), infrared, and other wireless media. Combinations of any of the above can also be included within the scope of computer-readable media.

FIG. 2A is a block diagram of an example of a tester control system 110 capable of implementing embodiments of the present disclosure. Tester control system 110 broadly represents any single or multi-processor computing device or system capable of executing computer-readable instructions. Examples of control system 110 include, without limitation, workstations, laptops, client-side terminals, servers, distributed computing systems, handheld devices, or any other computing system or device. In its most basic configuration, control system 110 may include at least one processor 114 and a system memory 116.

Processor 114 generally represents any type or form of processing unit capable of processing data or interpreting and executing instructions. In certain embodiments, processor 114 may receive instructions from a software application or module. These instructions may cause processor 114 to perform the functions of one or more of the example embodiments described and/or illustrated herein.

System memory 116 generally represents any type or form of volatile or non-volatile storage device or medium capable of storing data and/or other computer-readable instructions. Examples of system memory 116 include, without limitation, RAM, ROM, flash memory, or any other suitable memory device. Although not required, in certain embodiments control system 110 may include both a volatile memory unit (such as, for example, system memory 116) and a non-volatile storage device (such as, for example, primary storage device 132).

Tester control system 110 may also include one or more components or elements in addition to processor 114 and system memory 116. For example, in the embodiment of FIG. 2A, control system 110 includes a memory controller 118, an input/output (I/O) controller 120, and a communication interface 122, each of which may be interconnected via a communication infrastructure 112. Communication infrastructure 112 generally represents any type or form of infrastructure capable of facilitating communication between one or more components of a computing device. Examples of communication infrastructure 112 include, without limitation, a communication bus (such as an Industry Standard Architecture (ISA), Peripheral Component Interconnect (PCI), PCI Express (PCIe), or similar bus) and a network.

Memory controller 118 generally represents any type or form of device capable of handling memory or data or controlling communication between one or more components of control system 110. For example, memory controller 118 may control communication between processor 114, system memory 116, and I/O controller 120 via communication infrastructure 112.

I/O controller 120 generally represents any type or form of module capable of coordinating and/or controlling the input and output functions of a computing device. For example, I/O controller 120 may control or facilitate transfer of data between one or more elements of control system 110, such as processor 114, system memory 116, communication interface 122, display adapter 126, input interface 130, and storage interface 134.

Communication interface 122 broadly represents any type or form of communication device or adapter capable of facilitating communication between example control system 110 and one or more additional devices. For example, communication interface 122 may facilitate communication between control system 110 and a private or public network including additional control systems. Examples of communication interface 122 include, without limitation, a wired network interface (such as a network interface card), a wireless network interface (such as a wireless network interface card), a modem, and any other suitable interface. In one embodiment, communication interface 122 provides a direct connection to a remote server via a direct link to a network, such as the Internet. Communication interface 122 may also indirectly provide such a connection through any other suitable connection.

Communication interface 122 may also represent a host adapter configured to facilitate communication between control system 110 and one or more additional network or storage devices via an external bus or communications channel. Examples of host adapters include, without limitation, Small Computer System Interface (SCSI) host adapters, Universal Serial Bus (USB) host adapters, IEEE (Institute of Electrical and Electronics Engineers) 1394 host adapters, Serial Advanced Technology Attachment (SATA) and External SATA (eSATA) host adapters, Advanced Technology Attachment (ATA) and Parallel ATA (PATA) host adapters, Fibre Channel interface adapters, Ethernet adapters, or the like. Communication interface 122 may also allow control system 110 to engage in distributed or remote computing. For example, communication interface 122 may receive instructions from a remote device or send instructions to a remote device for execution.

As illustrated in FIG. 2A, control system 110 may also include at least one display device 124 coupled to communication infrastructure 112 via a display adapter 126. Display device 124 generally represents any type or form of device capable of visually displaying information forwarded by display adapter 126. Similarly, display adapter 126 generally represents any type or form of device configured to forward graphics, text, and other data for display on display device 124.

As illustrated in FIG. 2A, control system 110 may also include at least one input device 128 coupled to communication infrastructure 112 via an input interface 130. Input device 128 generally represents any type or form of input device capable of providing input, either computer- or human-generated, to control system 110. Examples of input device 128 include, without limitation, a keyboard, a pointing device, a speech recognition device, or any other input device.

As illustrated in FIG. 2A, control system 110 may also include a primary storage device 132 and a backup storage device 133 coupled to communication infrastructure 112 via a storage interface 134. Storage devices 132 and 133 generally represent any type or form of storage device or medium capable of storing data and/or other computer-readable instructions. For example, storage devices 132 and 133 may be a magnetic disk drive (e.g., a so-called hard drive), a floppy disk drive, a magnetic tape drive, an optical disk drive, a flash drive, or the like. Storage interface 134 generally represents any type or form of interface or device for transferring data between storage devices 132 and 133 and other components of control system 110.

In one example, databases 140 may be stored in primary storage device 132. Databases 140 may represent portions of a single database or computing device or it may represent multiple databases or computing devices. For example, databases 140 may represent (be stored on) a portion of control system 110 and/or portions of example network architecture 100 in FIG. 2B (below). Alternatively, databases 140 may represent (be stored on) one or more physically separate devices capable of being accessed by a computing device, such as control system 110 and/or portions of network architecture 100.

Continuing with reference to FIG. 2A, storage devices 132 and 133 may be configured to read from and/or write to a removable storage unit configured to store computer software, data, or other computer-readable information. Examples of suitable removable storage units include, without limitation, a floppy disk, a magnetic tape, an optical disk, a flash memory device, or the like. Storage devices 132 and 133 may also include other similar structures or devices for allowing computer software, data, or other computer-readable instructions to be loaded into control system 110. For example, storage devices 132 and 133 may be configured to read and write software, data, or other computer-readable information. Storage devices 132 and 133 may also be a part of control system 110 or may be separate devices accessed through other interface systems.

Many other devices or subsystems may be connected to control system 110. Conversely, all of the components and devices illustrated in FIG. 2A need not be present to practice the embodiments described herein. The devices and subsystems referenced above may also be interconnected in different ways from that shown in FIG. 2A. Control system 110 may also employ any number of software, firmware, and/or hardware configurations. For example, the example embodiments disclosed herein may be encoded as a computer program (also referred to as computer software, software applications, computer-readable instructions, or computer control logic) on a computer-readable medium.

The computer-readable medium containing the computer program may be loaded into control system 110. All or a portion of the computer program stored on the computer-readable medium may then be stored in system memory 116 and/or various portions of storage devices 132 and 133. When executed by processor 114, a computer program loaded into control system 110 may cause processor 114 to perform and/or be a means for performing the functions of the example embodiments described and/or illustrated herein. Additionally or alternatively, the example embodiments described and/or illustrated herein may be implemented in firmware and/or hardware.

FIG. 2B is a block diagram of an example of a network architecture 100 in which client systems 151, 152 and 153 and servers 141 and 145 may be coupled to a network 150. Client systems 151, 152 and 153 generally represent any type or form of computing device or system, such as tester control system 110 of FIG. 2A.

Similarly, servers 141 and 145 generally represent computing devices or systems, such as application servers or database servers, configured to provide various database services and/or run certain software applications. Network 150 generally represents any telecommunication or computer network including, for example, an intranet, a wide area network (WAN), a local area network (LAN), a personal area network (PAN), or the Internet.

With reference to control system 110 of FIG. 2A, a communication interface, such as communication interface 122, may be used to provide connectivity between each client system 151, 152 and 153 and network 150. Client systems 151, 152 and 153 may be able to access information on server 141 or 145 using, for example, a Web browser or other client software. Such software may allow client systems 151, 152 and 153 to access data hosted by server 140, server 145, storage devices 160(1)-(L), storage devices 170(1)-(N), storage devices 190(1)-(M), or intelligent storage array 195. Although FIG. 2B depicts the use of a network (such as the Internet) for exchanging data, the embodiments described herein are not limited to the Internet or any particular network-based environment.

In one embodiment, all or a portion of one or more of the example embodiments disclosed herein are encoded as a computer program and loaded onto and executed by server 141, server 145, storage devices 160(1)-(L), storage devices 170(1)-(N), storage devices 190(1)-(M), intelligent storage array 195, or any combination thereof. All or a portion of one or more of the example embodiments disclosed herein may also be encoded as a computer program, stored in server 141, run by server 145, and distributed to client systems 151, 152 and 153 over network 150.

Cloud Based Infrastructure for Supporting Protocol Reconfigurations in Protocol Independent Device Testing Systems

In conventional systems, the communication protocol used to communicate with the devices under test (DUTs) is fixed because the hardware bus adapter cards that plug into the ATE body are typically single purpose devices that are designed to communicate in only one protocol and cannot be reprogrammed to communicate in a different protocol. Tester re-configurability can be usually be improved in a number of ways. One way is by configuring the hardware so that the protocol engine used to communicate with the DUTs is programmed directly on reprogrammable FPGA devices on the tester apparatus instead of fixing the protocol engine in firmware within the tester processor. Further, the protocols used to program the FPGAs can be made available on a cloud based infrastructure so that the user can access and configure the testing protocols used on the FPGA devices directly from a network.

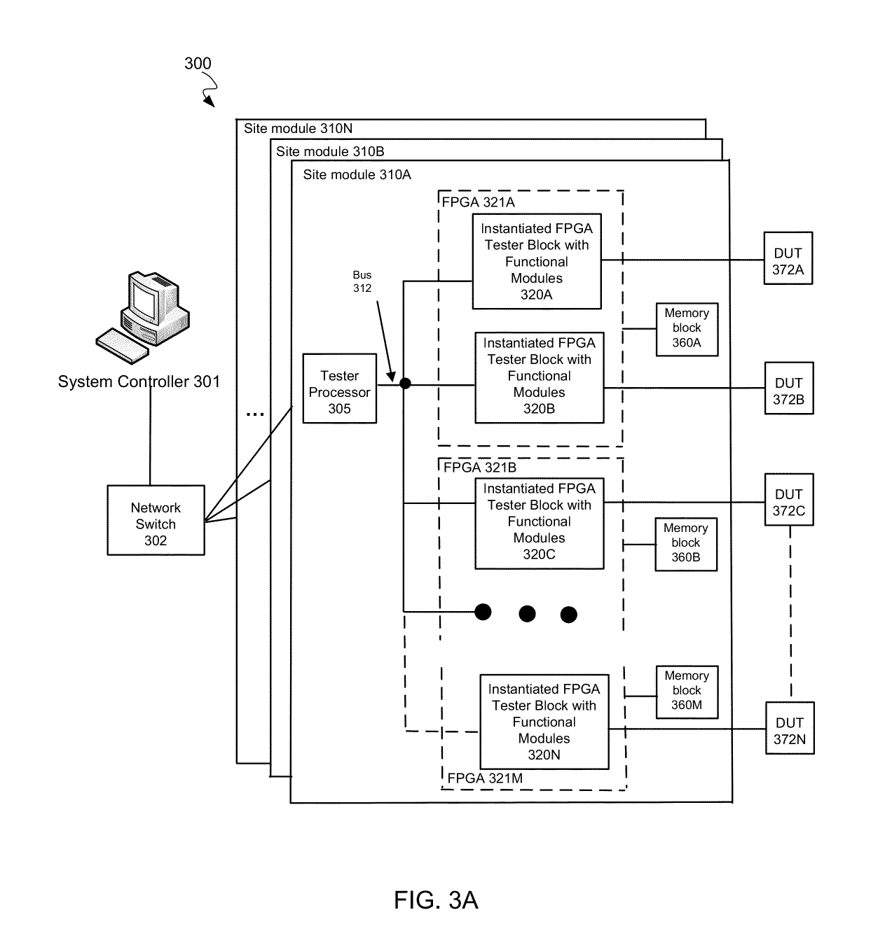

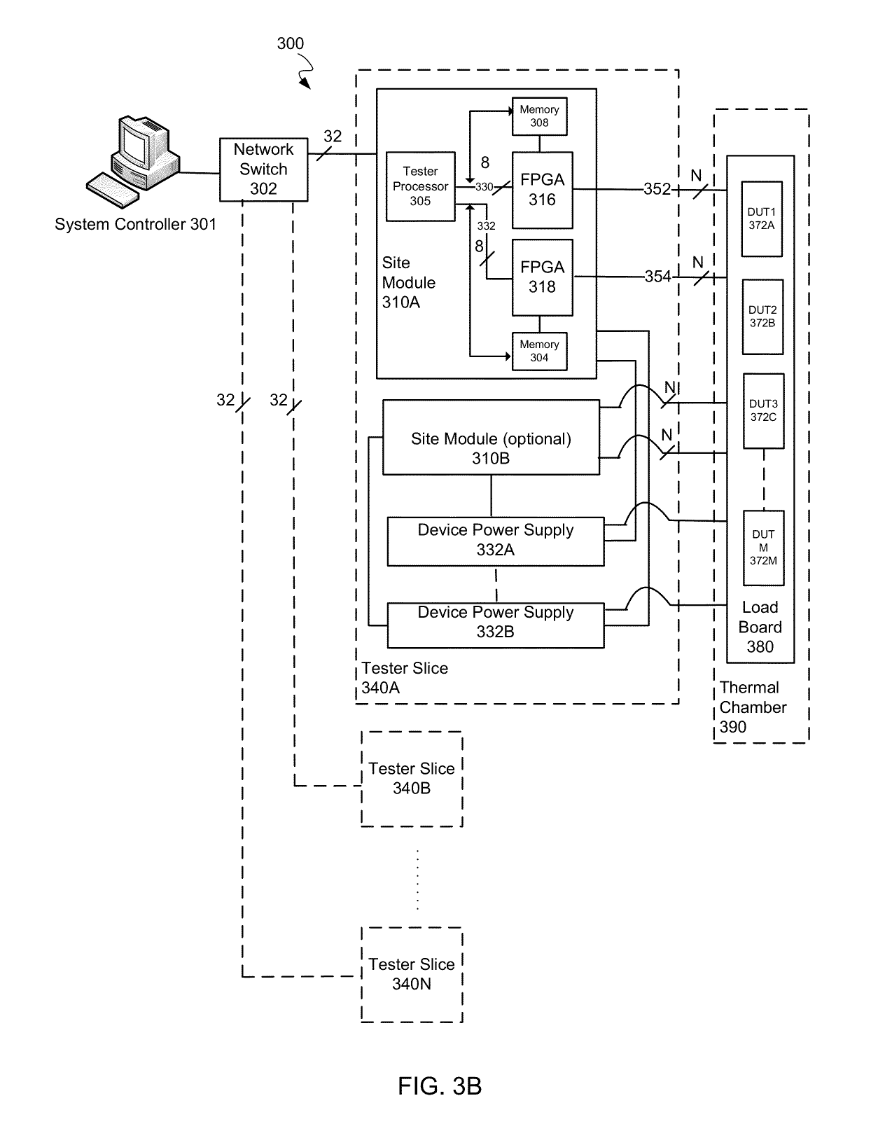

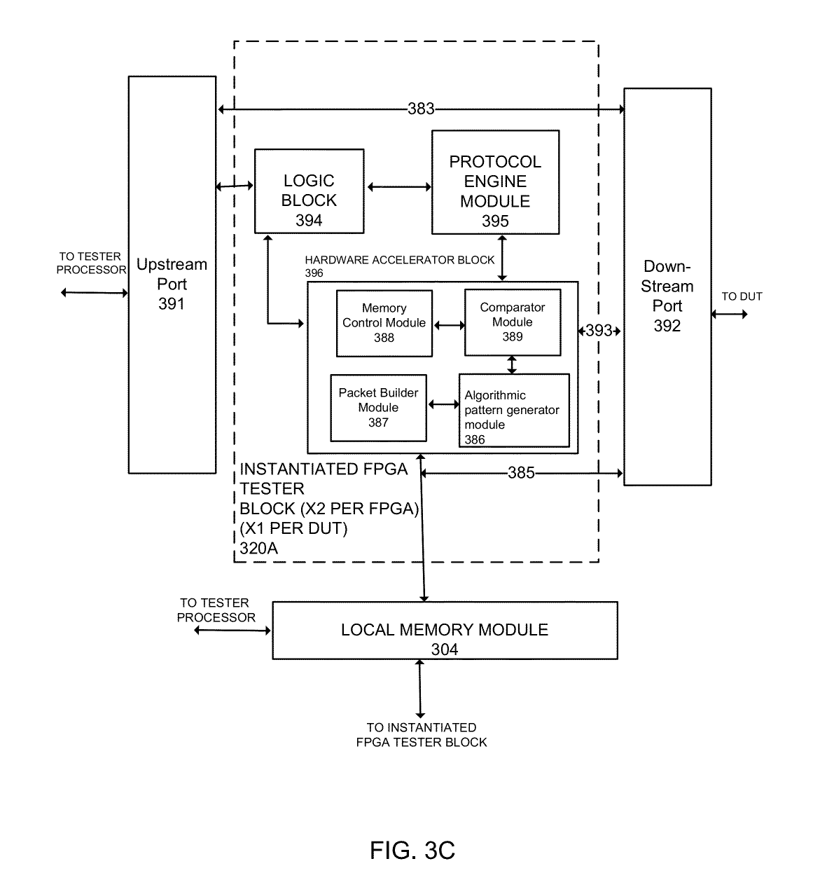

FIGS. 3A-3C illustrate one embodiment of an apparatus for hardware device testing wherein the communication protocol used to communicate with the DUTs is reconfigurable. However, the principles of the present invention can be used in conjunction with any apparatus wherein the apparatus can be reconfigured to communicate in any of several different protocols.

FIG. 3A is an exemplary high level block diagram of an automatic test equipment (ATE) apparatus 300 in which a system controller 301 controls a tester processor 305, which is connected to the devices under test (DUTs) through FPGA devices with built-in functional modules in accordance with an embodiment of the present invention. In one embodiment, ATE apparatus 300 may be implemented within any testing system capable of testing multiple DUTs simultaneously.

Referring to FIG. 3A, an ATE apparatus 300 for testing semiconductor devices more efficiently in accordance with an embodiment of the present invention includes a system controller 301, a network switch 302 connecting the system controller to the site module boards 310A-310N, FPGA devices 321A-321M comprising instantiated FPGA tester blocks 320A-320N, memory block modules 360A-360M wherein each of the memory blocks is connected to one of the FPGA devices 321A-321M, and the devices under test (DUTs) 372A-372N, wherein each device under test 372A-372N is connected to one of the instantiated FPGA tester blocks 320A-320N.

In one embodiment, the system controller 301 may be a computer system e.g. control system 110 that provides a user interface for the user of the ATE to load the test programs and run tests for the DUTs connected to the ATE 300. The Verigy Stylus™ Operating System is one example of test software or test application normally used during device testing. It provides the user with (i) a test development environment and (ii) a device testing environment. It also comprises a graphical user interface from which to configure and control the tests. It can also comprise functionality to control the test flow, control the status of the test program, determine which test program is running, and log test results and other data related to test flow. In one embodiment, the system controller can be connected to and control as many as 512 DUTs. Typically, the user also loads the test program into the system controller 301 through the graphical user interface. The test program defines all the parameters of the test that needs to be run on the DUTs.

In one embodiment, the system controller 301 can be connected to the site module boards 310A-310N through a network switch, such as an Ethernet switch. In other embodiments, the network switch may be compatible with a different protocol such as Fibre Channel, 802.11 or ATM, for instance.

In one embodiment, each of the site module boards 310A-310N may be a separate standalone board used for purposes of evaluation and development that attaches to custom-built load board fixtures, on which the DUTs 372A-372N are loaded, and also to the system controller 301 from where the test programs are received. In other embodiments, the site module boards may be implemented as plug-in expansion cards or as daughter boards that plug into a chassis connected to system controller 301.

The site module boards 310A-310N can each comprise at least one tester processor 305 and at least one FPGA device. The tester processor 305 and the FPGA devices 321A-321M on the site module board run the test methods for each test case in accordance with the test program instructions received from the system controller 301. In one embodiment the tester processor can be a commercially available Intel 8086 CPU or any other well-known processor. Further, the tester processor may be operating on the Ubuntu OS x64 operating system and running the Core Software, which allows it to communicate with the Stylus software running on the system controller, to run the test methods. The tester processor 305 controls the FPGA devices on the site module and the DUTs connected to the site module based on the test program received from the system controller. In one embodiment, the test methods reside on the system controller 301 and get pushed onto the tester processor 305 from the test application on system controller 301 depending on what protocol is being tested.

The tester processor 305 is connected to and can communicate with the FPGA devices over bus 312. In one embodiment, tester processor 305 communicates with each of the FPGA devices 321A-321M over a separate dedicated bus. In one embodiment, tester processor 305 can control the testing of the DUTs 372A-372N transparently through the FPGAs with minimal processing functionality allocated to the FPGA devices. In this embodiment, the data traffic over bus 312 can be exhausted rapidly because all the commands and data generated by the tester processor need to be communicated over the bus to the FPGA devices. In other embodiments, the tester processor 305 can share the processing load by allocating functionality to control the testing of the DUTs to the FPGA devices through a series of hardware acceleration modes. In these embodiments, the traffic over bus 312 is reduced because the FPGA devices can generate their own commands and data. This allows for low latency communication with the DUTs.

In one embodiment, each of the FPGA devices 321A-321M is connected to its own dedicated memory block 360A-360M. These memory blocks can, among other things, be utilized to store the test pattern data that is written out to the DUTs. In one embodiment, each of the FPGA devices can comprise two instantiated FPGA tester blocks 320A-320B with functional modules for performing functions including implementation of communicative protocol engines and hardware accelerators as described further herein. Memory blocks 360A-360 M can each contain one or more memory modules, wherein each memory module within the memory block can be dedicated to one or more of the instantiated FPGA tester blocks 320A-320B. Accordingly, each of the instantiated FPGA tester blocks 320A-320B can be connected to its own dedicated memory module within memory block 360A. In another embodiment, instantiated FPGA tester blocks 320A and 320B can share one of the memory modules within memory block 360A.

Further, each of the DUTs 372A-372N in the system can be connected to a dedicated instantiated FPGA tester block 320A-320N in a “tester per DUT” configuration, wherein each DUT is connected to its own tester block. This allows separate test execution for each DUT. The hardware resources in such a configuration are designed in a manner to support individual DUTs with minimal hardware sharing. This configuration also allows many DUTs to be tested in parallel, where each DUT can be connected to its own dedicated FPGA tester block and run a different test program.

The architecture of the embodiment of the present invention depicted in FIG. 3A has some distinct advantages. For example, it eliminates the need for protocol-specific hardware bus adapter sockets and cards in the system because the communication protocol modules can be programmed directly on the instantiated FPGA tester blocks within the FPGA devices. The instantiated tester blocks can be configured to communicate with the DUTs in any protocols that the DUTs support. Accordingly, if DUTs with different protocol support need to be tested, they can be connected to the same system and the FPGAs can be reprogrammed with support for the associated protocols. As a result, one ATE body can be easily configured to test DUTs supporting many different types of protocols.

In one embodiment of the present invention, the test application running system controller 301 e.g. the Verigy Stylus™ has built-in functionality, as part of the test development environment, to allow the user control over the protocol to be programmed onto the FPGAs and the different hardware acceleration modes for the FPGAs. The user can, therefore, easily choose the protocol to program on the hardware and the level of hardware acceleration through a graphical user interface (GUI) associated with the test application. In one embodiment, the test application comprises a tester state machine to control the test program flow and control the status of the test program.

It should be noted that the present invention is not limited to accomplishing hardware re-configurability solely through the use of FPGA devices. In one embodiment, site modules 310A-310N communicating to the system controller 301 via tester processor 305 can be made reconfigurable through the use of any of various programmable logic devices, e.g., programmable logic arrays (“PLAs”), complex programmable logic devices (“CPLDs”), programmable array logic (“PALs”), etc. In a different embodiment, the protocol running on the site modules may be made reconfigurable through yet other means, such as having the test processor itself be reconfigurable. The tester processor in such a system can be a digital signal processor (DSP), for example. The components, functions and processes that comprise a reconfigurable tester processor are described in detail in the following patent: U.S. Pat. No. 7,590,903, titled “Re-configurable Architecture For Automated Test Equipment”, issued Sep. 15, 2009 by Volkerink, Eric, all of which is incorporated herein by reference.

In one embodiment, new protocols can be downloaded and installed directly on the FPGAs via a simple bit-stream download from a cache on system controller 301 without any kind of hardware interactions. The test application on the system controller 301, in one embodiment, may be configured to transmit the bit-stream when a user chooses a new protocol to be installed through the test application.

For example, the FPGAs 321A-321M in the ATE apparatus 300 can be configured with the PCIe protocol to test PCIe devices initially and subsequently reconfigured via a software download to test SATA devices. Also, if a new protocol is released, the FPGAs can easily be configured with that protocol via a bit-stream download instead of having to physically switch all the hardware bus adapter cards in the system. Finally, if a non-standard protocol needs to be implemented, the FPGAs can nonetheless be configured to implement such a protocol. If the non-standard protocol cannot be found within the test application on system controller 301, the test application can be configured to search server 141 and server 145 through network 150 to determine if it can find the relevant bit-file on the servers.

In another embodiment, the FPGAs 321A-321M can be configured to run more than one communicative protocol, wherein these protocols also can be downloaded from system controller 301 and configured through software. For instance, instantiated FPGA tester block 320A can be configured to run the PCIe protocol while instantiated FPGA tester block 320B can be configured to run the SATA protocol. This allows the tester hardware to test DUTs supporting different protocols simultaneously. FPGA 321A can now be connected to test a DUT that supports both PCIe and SATA protocols. Alternatively, it can be connected to test two different DUTs, one DUT supporting the PCIe protocol and the other DUT supporting the SATA protocol.

In one embodiment, the present invention can be used to test solid state drives. In other embodiments, DUTs, across various industries and target applications, running any protocol can be tested using the present invention. For example, DUTs from the automotive or solar panel industry could also be tested using techniques of the present invention without needing to make any significant hardware changes in the test apparatus 300 or any software changes to the test application on system controller 301.

FIG. 3B provides a more detailed schematic block diagram of the site module and its interconnections with the system controller and the DUTs in accordance with an embodiment of the present invention. Referring to FIG. 3B, the site modules of the ATE apparatus, in one embodiment, can be mechanically configured onto tester slices 340A-340N, wherein each tester slice comprises at least one site module. In certain typical embodiments, each tester slice can comprise two site modules and two device power supply boards. Tester slice 340A of FIG. 3, for example, comprises site modules 310A and 310B and device power supply boards 332A and 332B. However, there is no limit to the number of device power supply boards or site modules that can be configured onto a tester slice. Tester slice 340 is connected to system controller 301 through network switch 302. Network switch 302 can be connected to each of the site modules with a 32 bit wide bus.

Each of the device power supply boards 332A-332B can be controlled from one of the site modules 310A-310B. The software running on the tester processor 305 can be configured to assign a device power supply to a particular site module. In one embodiment, the site modules 310A-310B and the device power supplies 332A-332B are configured to communicate with each other using a high speed serial protocol, e.g., Peripheral Component Interconnect Express (PCIe), Serial AT Attachment (SATA) or Serial Attached SCSI (SAS), for instance.

In one embodiment, each site module is configured with two FPGAs as shown in FIG. 3B. Each of the FPGAs 316 and 318 in the embodiment of FIG. 3B is controlled by the tester processor 305 and performs a similar function to FPGAs 321A-321M in FIG. 2. The tester processor 305 can communicate with each of the FPGAs using a 8 lane high speed serial protocol interface such as PCIe as indicated by system buses 330 and 332 in FIG. 3B. In other embodiments, the tester processor 305 could also communicate with the FPGAs using different high speed serial protocols, e.g., Serial AT Attachment (SATA) or Serial Attached SCSI (SAS) or any other high speed protocol.

FPGAs 316 and 318 are connected to memory modules 308 and 304 respectively. The memory modules are coupled with and can be controlled by both the FPGA devices and the tester processor 305.

FPGAs 316 and 318 can be connected to the DUTs 372A-372M on the load board 380 through buses 352 and 354 respectively. In one embodiment, the load board 380 is a physical harness that allows a general purpose high speed connection at the site module end that is agnostic to the protocol used to communicate to the DUTs on lines 352 and 354. At the DUT end, however, the load board needs to be designed so as to have connectors specific to the protocol being used by the DUT.

The DUTs 372A-372M, in one embodiment of the invention, are loaded on a load board 380 that is placed inside a thermal chamber 390 for testing. The DUTs 372A-372M and the load board 380 derive power from the device power supplies 332A and 332B.

FIG. 3C is a detailed schematic block diagram of an instantiated FPGA tester block of FIG. 3A according to an embodiment of the present invention.

Referring to FIG. 3C, the instantiated FPGA tester block 320A is connected to the tester processor 305 through upstream port 391 and to the DUT through downstream port 392.

Instantiated FPGA block 320A can comprise a protocol engine module 395, a logic block module 394, and a hardware accelerator block 396. The hardware accelerator block 396 can further comprise a memory control module 388, comparator module 389, a packet builder module 387, and an algorithmic pattern generator (APG) module 386.

In one embodiment, logic block module 394 comprises decode logic to decode the commands from the tester processor, routing logic to route all the incoming commands and data from the tester processor 305 and the data generated by the FPGA devices to the appropriate modules, and arbitration logic to arbitrate between the various communication paths within instantiated FPGA tester block 320A.

In one implementation, the communication protocol used to communicate between the tester processor and the DUTs can advantageously be reconfigurable. The communicative protocol engine in such an implementation is programmed directly into the protocol engine module 395 of instantiated FPGA tester block 320A. The instantiated FPGA tester block 320A can therefore be configured to communicate with the DUTs in any protocol that the DUTs support. This advantageously eliminates the need for hardware bus adapter cards and no protocol-specific hardware need be replaced to test DUTs with different protocol support. In one embodiment, the protocols can be high speed serial protocols, including but not limited to SATA, SAS or PCIe, etc.

As stated above, the new or modified protocols can be downloaded and installed directly on the FPGAs via a simple bit-stream download from the system controller through the tester processor without any kind of hardware interactions. Initial setup of the test apparatus can comprise choosing one or more protocols from a library of available protocols on system controller 301 to be configured onto the FPGA devices. The protocols are cached as files on the system controller 301 and can be downloaded as bit files onto the FPGAs. The user can select the protocol from a list of releases available through the graphical user interface of the test application running on system controller 301. Before a protocol is made available as an option, it has to be built, tested and integrated into a release. FPGA configurations that are released, among other things, contain definitions regarding the protocols supported and the number of transceivers available to connect DUTs. The library of releases can then be made available to a user through the graphical user interface.

Also, if a new protocol is released, the FPGAs can easily be configured with that protocol via a software download. In one embodiment of the present invention, the protocol can first be downloaded to the system controller 301 through network 150, for example, using communication interface 122, wherein the protocols are stored on servers 141 and 145. A user needing the protocol can access the servers 141 and 145 through a website, wherein access to the website is controlled through user specific logins and passwords. In this way, in one embodiment, the present invention includes functionality for controlling user access to servers for accessing the protocol modules to be programmed onto the protocol engine module 395 of the FPGA tester block 320A.

In FIG. 3C, if the DUT coupled to the downstream port 392, for example, is a PCIe device, a bit-file containing the instantiation of the PCIe protocol can be downloaded through the upstream port 391 and installed on the protocol engine module 395. Each FPGA device 316 or 318 can comprise one or more instantiated FPGA tester block and, consequently, one or more protocol engine modules. The number of protocol engine modules that any one FPGA device can support is limited only by the size and gate count of the FPGA.

In one embodiment of the present invention, each of the protocol engine modules within a FPGA device can be configured with a different communicative protocol. Accordingly, an FPGA device can be connected to test multiple DUTs, each supporting a different communicative protocol simultaneously. Alternatively, an FPGA device can be connected to a single DUT supporting multiple protocols and test all the modules running on the device simultaneously. For example, if an FPGA is configured to run both PCIe and SATA protocols, it can be connected to test a DUT that supports both PCIe and SATA protocols. Alternatively, it can be connected to test two different DUTs, one DUT supporting the PCIe protocol and the other DUT supporting the SATA protocol.

The hardware accelerator block 396 of FIG. 3C can be used to expedite certain functions on FPGA hardware faster than would be possible to do in software on the tester processor. The hardware accelerator block 396 can supply the initial test pattern data used in testing the DUTs. It can also contain functionality to generate certain commands used to control the testing of the DUTs. To generate test pattern data, accelerator block 396 uses the algorithmic pattern generator module 386.

The hardware accelerator block 396 can use comparator module 389 to compare the data being read from the DUTs to the data that was written to the DUTs in a prior cycle. The comparator module 389 comprises functionality to flag a mismatch to the tester processor 305 to identify devices that are not in compliance. More specifically, the comparator module 389 can comprise an error counter that keeps track of the mismatches and communicates them to the tester processor 305.

Hardware accelerator block 396 can connect to a local memory module 304. Memory module 304 performs a similar function to a memory module within any of the memory blocks 360A-360M. Memory module 360A can be controlled by both the hardware accelerator block 396 and the tester processor 305. The tester processor 305 can control the local memory module 304 and write the initial test pattern data to it.

The memory module 304 stores the test pattern data to be written to the DUTs and the hardware accelerator block 396 accesses it to compare the data stored to the data read from the DUTs after the write cycle. The local memory module 304 can also be used to log failures. The memory module would store a log file with a record of all the failures the DUTs experienced during testing. In one embodiment, the accelerator block 396 has a dedicated local memory module block 394 that is not accessible by any other instantiated FPGA tester blocks. In another embodiment, the local memory module block 304 is shared with a hardware accelerator block in another instantiated FPGA tester block.

Hardware accelerator block 396 can also comprise a memory control module 388. The memory control module 388 interacts with and controls read and write access to the memory module 304.

Finally, hardware accelerator block 396 comprises a packet builder module 387. The packet builder module is used by the hardware accelerator block in certain modes to construct packets to be written out to the DUTs comprising header/command data and test pattern data.

In certain embodiments, hardware accelerator block 396 can be programmed through the tester processor 305 to operate in one of several modes of hardware acceleration. In one embodiment, the instructions for the hardware acceleration mode the FPGA tester block 320A to operate in is received from the test application running on system controller 301. In this embodiment, the test application on system controller 301 has visibility and control over the hardware acceleration modes for the various FPGA tester blocks in the system.

In bypass mode, the hardware accelerator is bypassed and commands and test data are sent by the tester processor 305 directly to the DUT through path 383. In hardware accelerator pattern generator mode, test pattern data is generated by the APG module 386 while the commands are generated by the tester processor 305. The test packets are transmitted to the DUT through path 393. In hardware accelerator memory mode, the test pattern data is accessed from local memory module 304 while the commands are generated by the tester processor 305. The test pattern data is transmitted to the DUT through path 385. Routing logic is needed to arbitrate between paths 385, 393, and 383 to control the flow of data to the DUT.

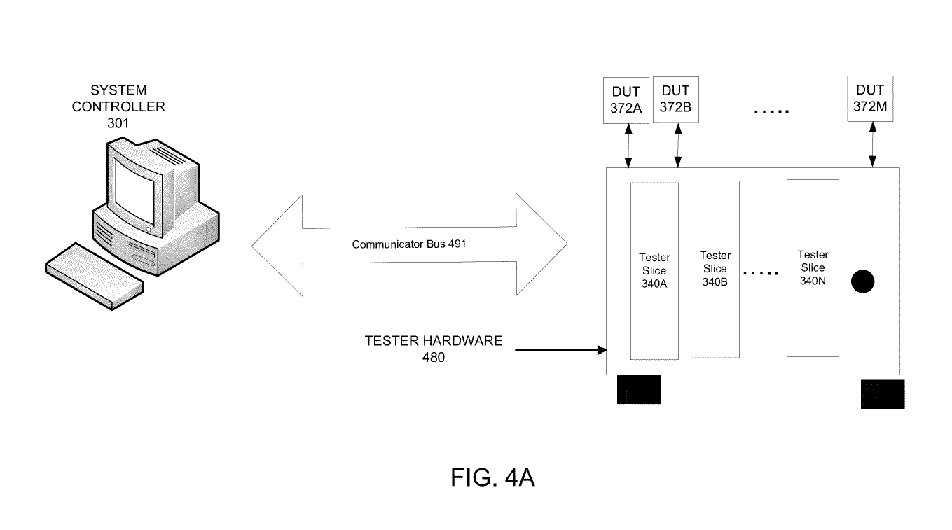

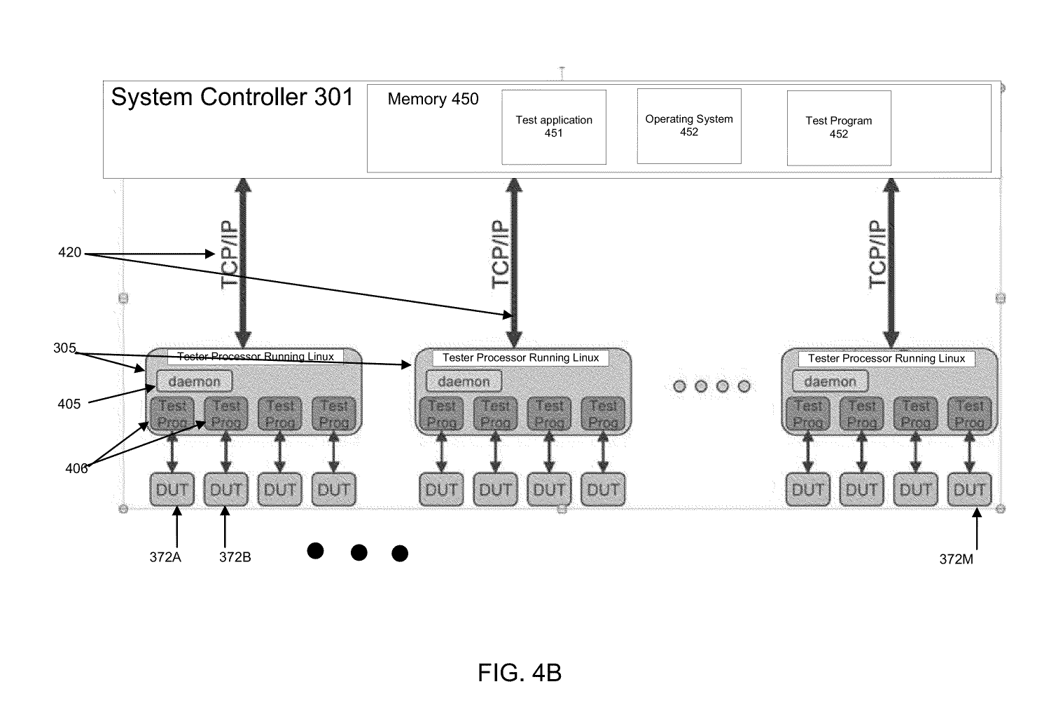

FIG. 4A is a schematic block diagram illustrating a typical hardware configuration for connecting the system controller with the tester slices and DUTs in the system in accordance with an embodiment of the present invention.

In one embodiment, the system controller 301 comprises one or more linked computers running the test application e.g. Verigy Stylus™ Operating System. In other embodiments, the system controller often comprises only a single computer. The system controller 301 is the overall system control unit, and runs the test application with the graphical user interface (GUI) that is responsible for accomplishing all the user-level testing tasks, including running the user's main test application.

The communicator bus 491 provides a high-speed electronic communication channel between the system controller and the tester hardware. The communicator bus can also be referred to as a backplane, a module connection enabler, or system bus. Physically, communicator bus 491 is a fast, high-bandwidth duplex connection bus that can be electrical, optical, etc. System controller 301 sets up the conditions for testing the DUTs 372A-372M by programming the tester hardware through commands sent over the communicator bus 491.

Tester hardware 480 comprises the complex set of electronic and electrical parts and connectors necessary to provide the test stimulus to the devices under test (DUTs) 372A-372M and measure the response of the DUTs to the stimulus, and compare it against the expected response. The tester slices 340A-340N, as discussed in relation to FIG. 3B, are housed within tester hardware 480. In one embodiment, tester hardware 480 is housed in the thermal chamber 390 as depicted in FIG. 3B.

FIG. 4B is a schematic block diagram illustrating exemplary software components of the site modules and the system controller of the automated test system in accordance with one embodiment of the present invention.

As shown in FIG. 4B, system controller 301 comprises memory 450. Memory 450 stores various constructs including, among other things, an operating system 452, e.g. Microsoft Windows™ Operation System, a test application 451 and a test program 452. One or more of these constructs can be provided to memory 450 through a computer program product (e.g., one or more diskettes or tape) or downloaded from the cloud (e.g., servers 141 and 145) through network 150. Preferably, the test application 451 is provided by the manufacturer of the ATE apparatus 300 to the ATE end user via a computer program product or downloaded through a network interface (not shown) from the cloud.

The system controller 301 operates in accordance with the operating system 452 and the test application 451. The test application 451 provides the user with a test development environment and a device testing environment. As indicated above, the Verigy Stylus™ Operating System is one example of a test application normally used during device testing. The test application provides a graphical user interface (GUI) to enable a user to create the test program(s) 452 when operating within the test development environment and to test all the DUTs 372A-372M connected to system controller 301 in accordance with the test program when operating within the device testing environment. In one embodiment, there's only one copy of the test application running on the operating system 452 and it is a single user application.

In one embodiment, the test application provides the user with a GUI that allows the user to configure the FPGAs or other programmable devices within apparatus 300 in different acceleration modes. For example, the test application 451 can provide the user with a graphical user interface to selectively program the FPGAs in the test apparatus 300 in either bypass mode, hardware accelerator pattern generator mode, hardware accelerator memory mode or packet builder mode. This is advantageous over conventional systems because the user now has added control through the graphical user interface of test application 451 over the hardware acceleration modes of the programmable devices on the site modules 310A-310N. In one embodiment, the test application can provide the user with a GUI to allow the user to communicate with the DUTs directly and bypass the FPGAs.

The test program 452 comprises all user-defined data and control flows that are necessary to perform a semiconductor device test on an ATE system. It runs on the system controller 301 within the development environment provided by the test application 451 running on the system controller 301. The main control flow in a test program, which dictates the sequence of individual tests to be applied to the DUTs, and the order in which the tests will be applied (which is dependent on the results of individual tests), is referred to as the test program flow. Typically, the user loads the test program into the system controller 301 through the graphical user interface running on the test application. The test program defines all the parameters of the test that needs to be run on the DUTs. The system controller can also comprise routing logic to route instructions for a particular test program to the tester processor 305 connected to the DUT controlled by the test program.

Test application 451 comprises a state machine that performs the sequencing of the tests based on the information contained in test program 452. Based on the test program flow, the state machine within test application 451 will keep track of which tests are running and what decisions need to be taken based on either “Pass” or “Fail” outcomes of those tests.

The system controller communicates with the tester processor 305 over a network interface 420, e.g., a TCP/IP connection. The tester processor 305, in one embodiment, runs on the Linux operating system and comprises a daemon 405 that runs as a background process. The daemon allows different task methods from the test program to be linked in. The task methods may be customizable by individual users based on user preferences.

Each instantiated FPGA tester block 320A can execute its own test program 400. This allows separate test execution for each DUT, 372A-372M since the “tester per DUT” architecture allows each DUT 372A-372M to be directly connected to its own dedicated instantiated FPGA tester block. Because the test application 451 performs the sequencing of tests, the tester processor 305 simply executes each test in accordance with the sequencing performed by the test application 451.

Further, the test application 451 is responsible for performing the “fan-out” for the test program flow, wherein the test application associates the various tests in the test program flow to the various DUTs connected to it for execution purposes. The user can prepare the test program flow as though it were written for a single DUT. However, the “fan out” feature allows the test program to be extended to and associated with several DUTs. Depending on the actual number of site modules and DUTs connected to the system controller 301, the test application 451 will perform a fan-out and instantiate the tests over multiple DUTs.

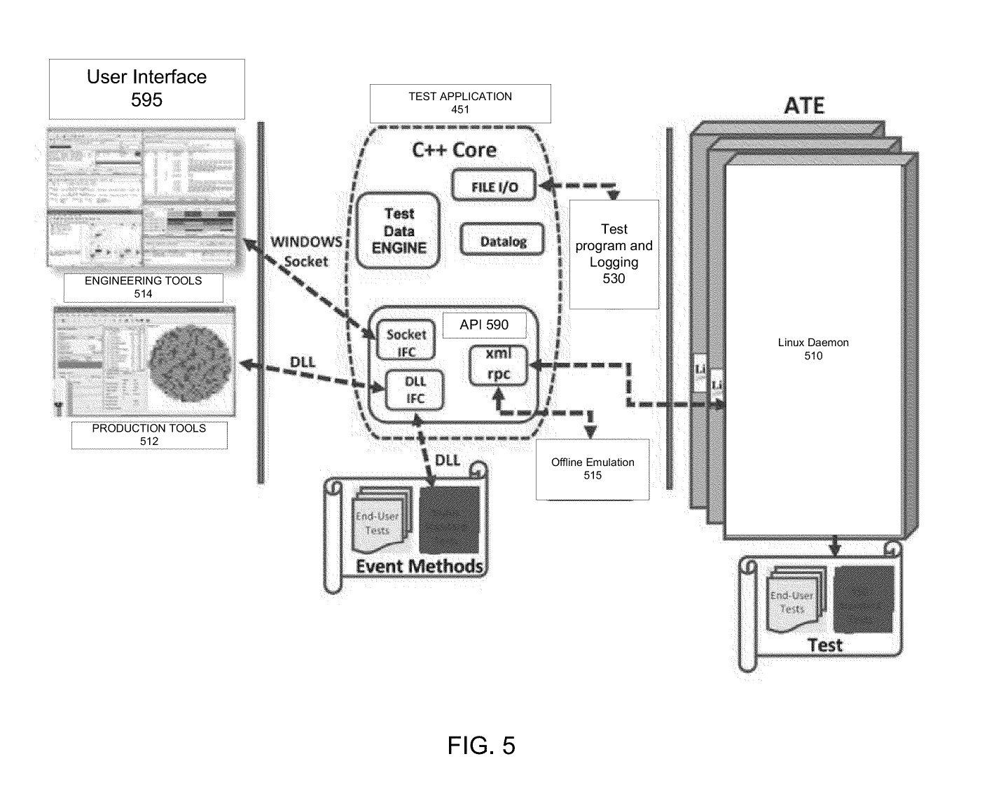

FIG. 5 is a schematic block diagram illustrating the architecture of the test application in accordance with one embodiment of the present invention. The intelligence of the tester apparatus 300 is built into test application 451 and controls, among other things, the status of the test program 452, the test program that is running at any given time, data-log and logging of the test program, and flow control.

The test program is loaded into the test application 451 using the Test Program and Logging Module 530. Test application 451 logs the results of the tests conveyed from the various tester processors 305 to module 530.

Offline Emulation module 515 emulates the Linux Daemon for when system controller 301 is not connected to a site module. Among other things, module 515 can be used for debugging purposes.

Test application 451 provides application programming interface (API) 590 for communicating between the Linux Daemon 510 and the graphical user interface 595. The user interface 595 comprises Engineering Tools 514 and Production Tools 512. Engineering Tools 514 is typically used by application and test engineers to develop a test program. Once a test program is approved to be production worthy, the test program is released into production. On the production floor, operators and technicians use the Production Tools 512 to execute the example test program. Therefore, Engineering Tools 514 allow the user to graphically edit the test program while Production Tools 512 does not.

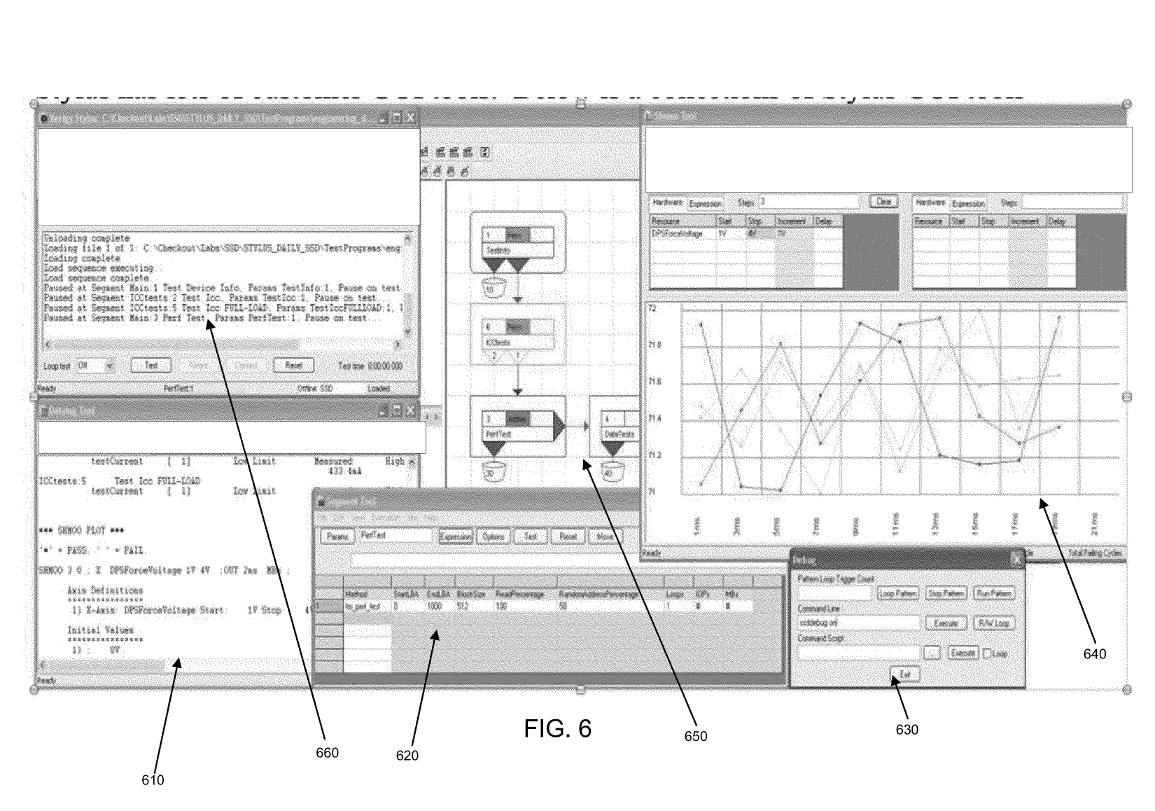

FIG. 6 illustrates an exemplary screen shot of a graphical user interface (GUI) for test application 451 illustrating the multiple tools available within the GUI in accordance with one embodiment of the present invention. Note that the functions of the various windows illustrated here may be present in different forms in different embodiments or may not be employed in others. The rearrangement of windows in the graphical user interface does not impede nor change the functionality of this embodiment of the present invention.

Window 610 illustrates a data log tool for user output data logging and display. Window 660 illustrates the engineering window from where the test program is loaded and run. Window 620 comprises the segment tool where tests and test parameters are specified by the user. Window 650 comprises the program flow tool where the test flow is put together. Finally window 640 comprises the shmoo tool, used for showing a graphical display of the response of a component or system varying over a range of conditions and inputs.

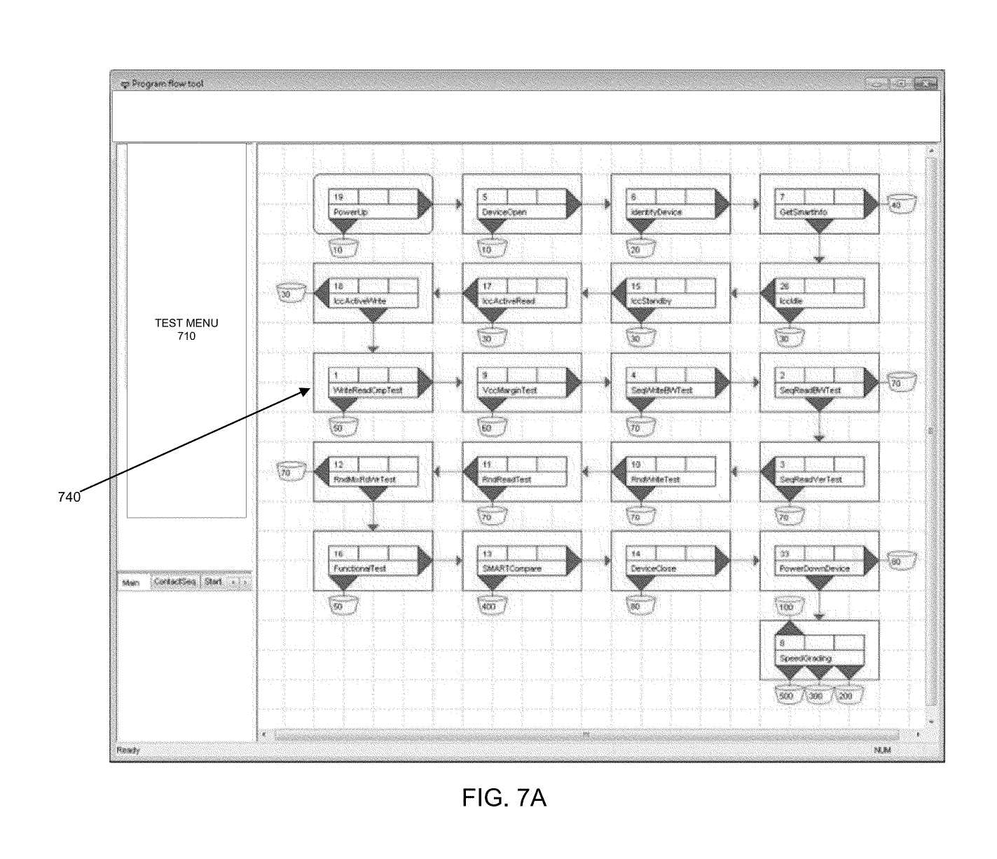

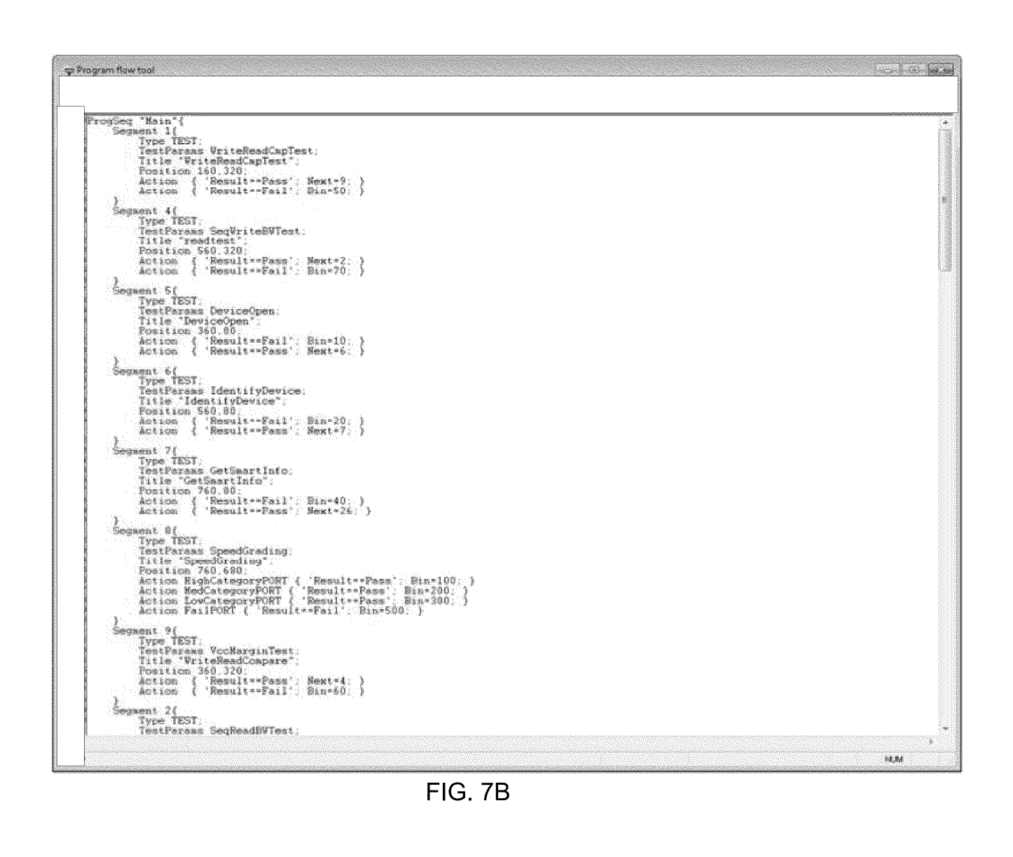

In one embodiment, the test application 451 can comprise a program flow tool. FIG. 7A illustrates a GUI implementation of a program flow tool in accordance with one embodiment of the present invention and FIG. 7B illustrates a text-based implementation of a program flow tool within the GUI in accordance with one embodiment of the present invention.

Each of the nodes 740 in the graphical program flow representation of FIG. 7A represents one or more tests that are to be run on the DUTs. Each node can comprise one or more tests. Further, the program flow tool can comprise decision making capability on steps to take depending on the outcome of each of the tests. Also, the user can choose how the tests need to be run using menu options. For example, the user can choose whether the test should be run until it passes or whether it should abort on first fail.

Test menu 710 allows the user to graphically choose between various different types of test, e.g. Functional Test, Smart Compare, Sequential Read Write Test, Identify Device etc. Based on the tests the user chooses to implement using the program flow tool, the test application 451 will push the appropriate tests down to the connected tester processors 305 and their corresponding site modules.

Any change a user makes in the program flow tool window of FIG. 7A is automatically reflected in the textual representation of the program flow as shown in FIG. 7B. Similarly, if the user chooses to prepare the test program using the textual program flow tool as shown in FIG. 7B, any changes to the script made by the user are automatically back annotated and reflected in the graphical window of the program flow tool shown in FIG. 7A.

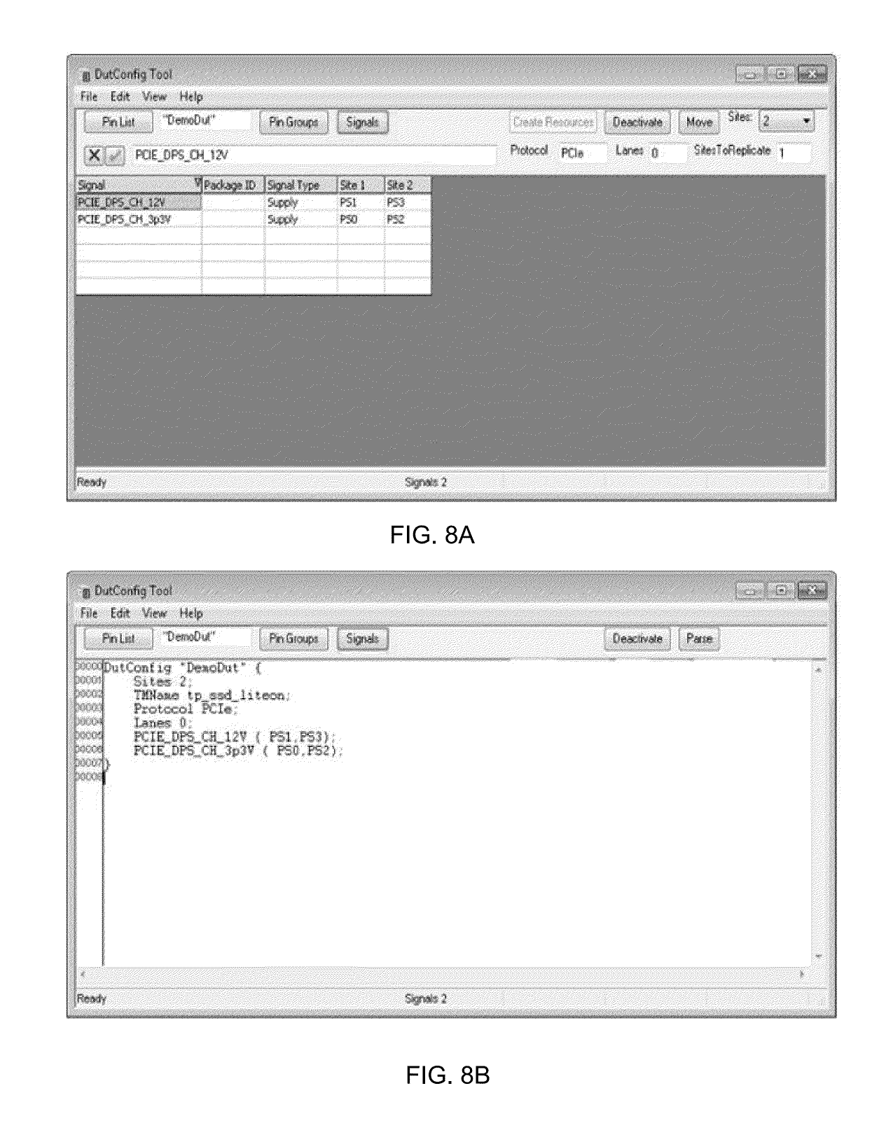

In one embodiment, the test application 451 can comprise a DUT configuration tool. FIG. 8A illustrates a GUI implementation of a DUT configuration tool within the graphical user interface in accordance with one embodiment of the present invention and FIG. 8B illustrates a textual implementation of a DUT configuration tool within the graphical user interface in accordance with one embodiment of the present invention. The DUT configuration tool in test application 451 allows the user to configure the DUT and the protocol used to communicate with it. The user, among other things, can also configure the number of instantiations of the DUT.

One embodiment of the present invention provides users the capability of implementing the protocol of their choice for communicating with the DUTs using the graphical user interface of test application 451. This eliminates the need for protocol-specific hardware bus adapter sockets and cards in the system because the communication protocol modules can be programmed directly on the site modules on either programmable FPGA devices, digital signal processors (DSPs) or any other programmable device. Further, the DUT configuration tool allows the user to switch to a different protocol to communicate with the DUT by either manipulating the GUI of FIG. 8A or editing text in the window displayed in FIG. 8B. The test application 451 is programmed with the intelligence to push the bit-files for the protocol configuration down to the programmable devices on the site modules based on the user's selections. In one embodiment, the test application 451 can automatically choose the tests that need to be run based on the user's protocol selection. For example, if the user chooses PCIe as the protocol, the test application 451 will automatically choose the corresponding tests associated with the PCIe protocol and communicate to the tester processor 305 to run those tests.

Further, by changing the number of “sites” within either the GUI or text based implementation, the user can easily edit the number of DUTs connected to the system for fan-out purposes. As a result, the user is allowed to prepare the test program without needing to account for the number of DUTs connected to the test apparatus. The number of DUTs can be changed within the DUT configuration tool and the test application 451 has the intelligence to create a fan-out based on the number of DUTs connected.

Similar to the program flow tool illustrated in FIGS. 7A and 7B, the DUT configuration tool also implements tracking between the text and GUI versions of the tools so that any change made in one of the two is automatically also implemented in the other. For example, if the number of sites chosen in the text window of FIG. 8B is increased, the corresponding number of rows in the GUI of FIG. 8A will increase to reflect that change, where each row is dedicated to one of the sites.

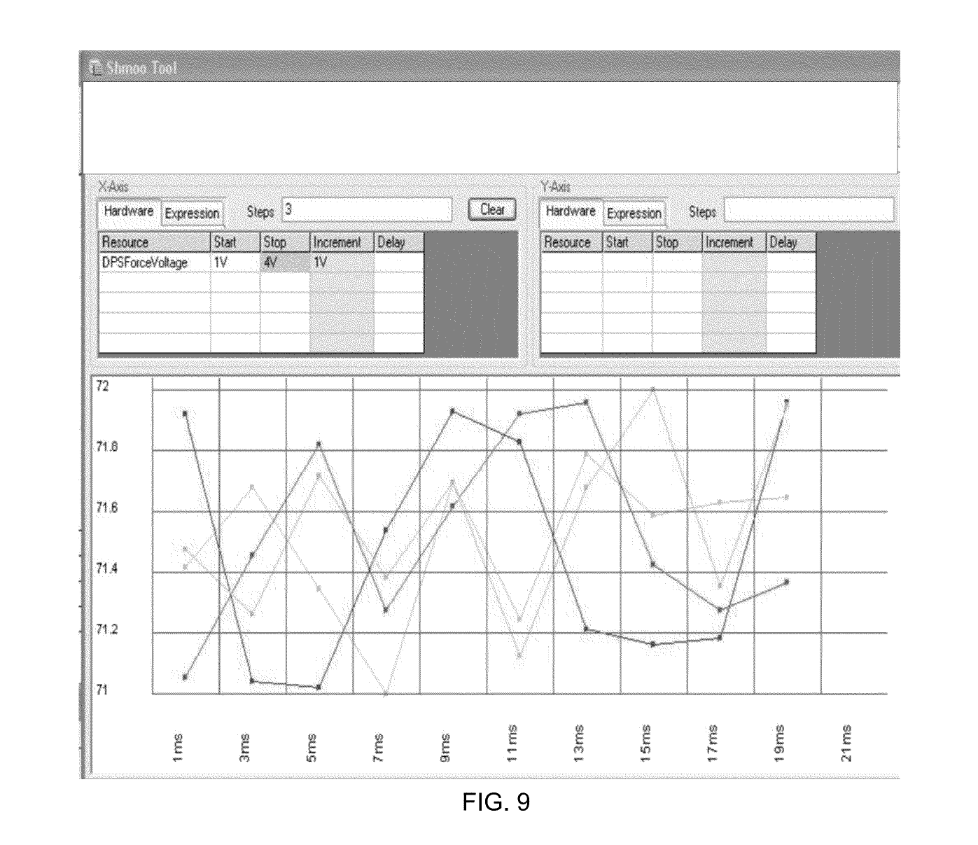

FIG. 9 illustrates the GUI for a shmoo tool within the test application in accordance with an embodiment of the present invention. In one embodiment, the test application 451 provides a GUI to implement a “single click” shmoo tool that is used for characterization purposes. Among other things, the shmoo tools presents a graphical display of the response of a component or system varying over a range of conditions and inputs.

In one embodiment, the shmoo tool of test application 451 allows the user to run the tests within the program flow multiple times, but with varying parameters, e.g., different read/write block sizes and provide a graphical representation of the results, e.g., how the throughput varies with the block sizes. In conventional systems, the user had to manually change the parameters for the tests before re-running them. The one-click shmoo tool within the test application 451 of the present invention allows the users to simply click an icon within a GUI window to start running the multiple tests with varying parameters. The user, however, does need to configure the shmoo tool beforehand with certain criteria for the tests, e.g., the number of steps, the increment between the inputs for each test, the stop conditions, etc. The shmoo tool, therefore, allows the user to set up an entire program flow, wherein tests are repeated with varying parameters, and invoke the program flow easily by clicking a GUI icon.

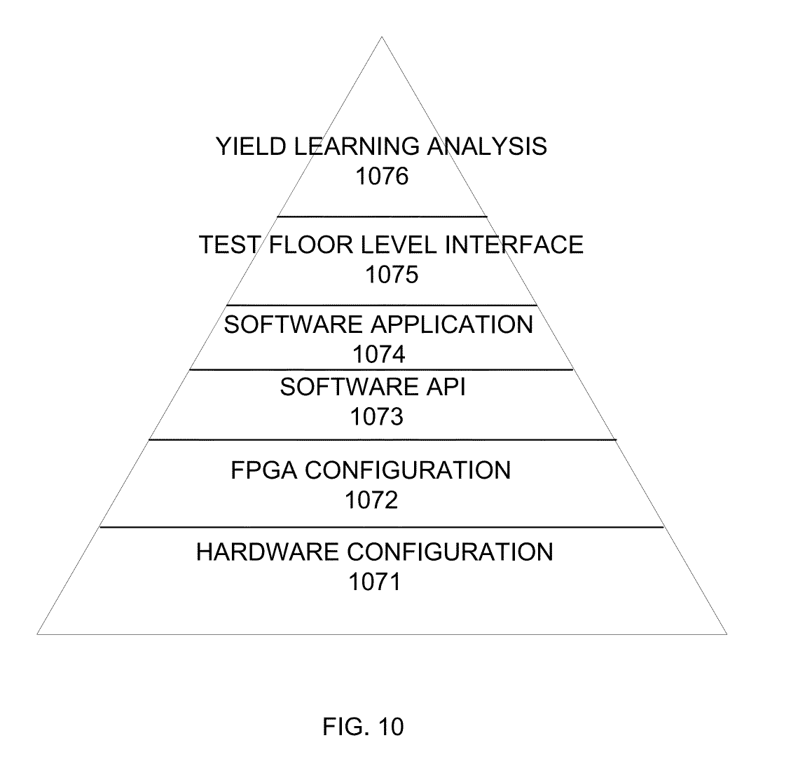

FIG. 10 illustrates an exemplary graphical representation of the layers of abstraction for an automated test system operating in accordance with one embodiment of the present invention. The hardware configuration layer 1071 defines the electrical and physical specifications of the system. For instance, it defines the connections between the system controller 301, the network switch 302, the site modules 310A-310N, and the DUTs 372A-372N. Also, it defines the connections between the various device power supplies and the site modules for supplying power to the system.

The FPGA configuration layer 1072 defines the specification for programming the site modules, including the FPGAs 320A-320N, with the necessary firmware including the protocols for communication with the DUTs, 372A-372N. Conventional tester systems typically lack this layer. By allowing for a FPGA configuration layer, the present invention provides for low latency integration and multiple levels of freedom to the user because of the ability to configure any of a various well-known or new protocols onto the FPGA. In one embodiment, the FPGA configuration layer can be replaced by a configuration layer for the type of programmable device being used on the site modules, e.g., DSPs.

Software API layer 1073 provides the programming interface between the system controller 301 and the site modules 310A-310N. Software API layer 1073 is different from similar API layers in conventional systems because it needs to provide for an interface for programming the FPGAs or other programmable devices on the site modules. For example, the API could allow for an FPGA configuration file to be passed down to the FPGA to program it with the appropriate protocol when the user makes the protocol selection in test application 451. The API would also, for example, need to create a translation from the user's instructions received through the GUI of test application 451 to a format that can be programmed onto the FPGA devices of the site modules. API 590 in FIG. 5, for example, provides the interface between the GUI of test application 451 and the FPGAs on the site modules 310A-310N.

The API can comprise a library of building blocks that have been developed to be instantiated on the FPGA. Each building block can comprise different categories of libraries for performing different functions. For example, the API may comprise a building block for configuring the receive ports on an FPGA to receive the appropriate communication protocol. The API performs a translation that leverages the library of building blocks to create the final configuration to be downloaded onto the FPGA.

Software application layer 1074, among other things, defines the GUI specification for test application 451 discussed above. The test application 451 provides the foundation to allow the user to capture test results and analyze the results. The data received from the site modules is translated to a format that is compatible with the test application. The test application subsequently routes the information to the pertinent building blocks and components that comprise the test application 451.

Test floor level interface layer 1075 defines the specification for allowing test application 451 to connect to and combine multiple site modules. For example, test floor level interface layer allows the user the ability to connect to and reconfigure an FPGA to switch from having three SATA ports and one PCIe port to having all PCIe ports through a GUI. The test floor level interface layer 1075 can also comprise building blocks to allow the test application to configure multiple ports at the same time. For example, this layer would comprise the specification to allow the user to test multiple ports, all using different protocols at the same time, or to alternate ports between different protocols in time.

Yield learning analysis layer 1076 defines the specification for combining yield data from multiple site modules. This layer is responsible for capturing the data from several different testers and combining it in a database for analysis of test results.

Layers 1074, 1075 and 1076 can also comprise building blocks related to a cloud interface in one embodiment of the present invention. In one embodiment, the cloud interface is configured to interface with a network 150, and servers 141 and 145, which are maintained by the developer of test application 451. The cloud interface can have several possible functions.

In one embodiment, users of the test system can access the network 150 through communication interface 122 on system controller 301 to download FPGA or other configuration files from servers 141 and 145. In another embodiment, access to servers 141 and 145 are restricted so that users need a login and password information to access the files. In one embodiment, users may be customers of the developer of the test application 451. Customer access can, for example, be customized for specific customers so that only configuration files and other content that the customer is allowed to access are made available through the cloud interface. For example, the customer's access may be limited to protocols and configurations that the customer has previously paid for. In one embodiment, the cloud interface can comprise a website through which the customers can access the desired files.

In one embodiment, the customer can modify the configuration files to customize the protocols to their own systems. The customer could then upload the modified files back to the servers 141 and 145 for other users of the system to have access to the configuration files.

In one embodiment, the FPGAs can be reconfigured directly through the cloud interface from a remote location. For example, the user could send instructions from servers 141 and 145 directly to a client device 151 to reconfigure the site modules connected to system controller 301 of the client device. This is advantageous because it allows remote configurations of the site modules without requiring the physical presence of a user on the test floor. Further, it allows client device 151 to be a dumb terminal, in one embodiment, while test application 451 can run on the remote servers from where the site modules are accessed.

In one embodiment, the test application can interface with the network 150 to access information from servers 141 and 145 associated with information from other testers regarding test results. The test application can then compile the information from all the various connected testers and present the results to a user via the GUI for test application 451. Alternatively, the test application can perform various types of test analyses and comparisons on the compiled information and present the results of the analyses and comparisons to the user via the GUI for test application 451. In one embodiment, the test application can upload the results of the tests to servers 141 and 145. By uploading the results back to the servers, the users of test application can access the results remotely. Also, it allows the developers of the configuration files and test application to easily diagnose any problems associated with the tests without needing to be physically present on the test floor. These functions, in one embodiment, can be performed by building blocks in the yield learning analysis layer 1076.

In one embodiment, the testers connected to client devices 151, 152 and 153 can be controlled directly via an instance of the test application 451 installed on server devices 141 and 145. In this embodiment, all the peripherals, e.g., keyboard, monitor etc. needed for the user to communicate with the test application 451 would be connected to server devices 141 and 145 (not shown).

The advantage of the exemplary architecture illustrated in FIG. 10 is that it allows the user the flexibility, at higher levels of test abstraction, to program different protocols on programmable devices for the testing of DUTs without sacrificing test quality issues.

FIG. 11 illustrates a flowchart of an exemplary computer implemented process for configuring a module comprising programmable devices with different protocols obtained over a network to test DUTs and receive test results for analysis in accordance with one embodiment of the present invention. The invention, however, is not limited to the description provided by flowchart 1100. Rather, it will be apparent to persons skilled in the relevant art(s) from the teachings provided herein that other functional flows are within the scope and spirit of the present invention. Flowchart 1100 will be described with continued reference to exemplary embodiments described above, though the method is not limited to those embodiments.

At step 1102, test application 451 obtains a protocol selection for programming one or more site modules 310A-310N from the user through the GUI of test application 451. The protocol, in one embodiment, can then be accessed in the form of a configuration file over network 150 from servers 141 and 145. The configuration file can be bit-files that are used to program the programmable devices, e.g., FPGAs, DSPs etc. on the site modules. As discussed above, servers 141 and 145 can, in one embodiment, be controlled by the developers of test application 451.

At step 1104, the test application 451 will configure the protocol for communicating with the DUTs using the DUT configuration module as illustrated in FIGS. 8A and 8B. The DUT configuration tool provides users the GUI to first select the protocol with which to communicate with the DUTs. In this way, test application 451 allows users the visibility to control the protocol used to communicate between the site modules 310A-310M and the DUTs 372A-372M.

At step 1106, test application 451 transmits instructions to the site modules to execute a sequence of tests comprising a program flow designed by the user to test the DUTs coupled to system controller 301. In one embodiment, the test application 451 transmits the sequence of tests received from the program flow tool illustrated in FIGS. 7A and 7B to the tester processor(s) 305 connected to the system controller 301 for execution. The test application comprises a state machine that keep tracks of the tests as they are running and determines which tests need to be executed next based on the sequence entered in the program flow tool. The program flow tool in FIGS. 7A and 7B controls the execution of test methods that are downloaded onto the site modules from system controller 301.

At step 1108, test application 451 receives results from the multiple connected site modules for the tests run on the connected DUTs. The test application 451 combines the data from the various tester modules and presents them to the user. The test application also contains functionality for analyzing the test results and presenting the results of the analysis to the user via the GUI for test application 451.

The foregoing description, for purpose of explanation, has been described with reference to specific embodiments. However, the illustrative discussions above are not intended to be exhaustive or to limit the invention to the precise forms disclosed. Many modifications and variations are possible in view of the above teachings. The embodiments were chosen and described in order to best explain the principles of the invention and its practical applications, to thereby enable others skilled in the art to best utilize the invention and various embodiments with various modifications as may be suited to the particular use contemplated.

What is claimed is:

1. A method for performing tests using automated test equipment (ATE), said method comprising:
obtaining a protocol selection for programming a programmable tester module using a graphical user interface (GUI);
accessing a configuration file associated with a protocol from a remote computer through a network;
configuring a programmable tester module with a communication protocol for application to at least one device under test (DUT) using the configuration file, wherein the programmable tester module is operable to be communicatively coupled to the at least one DUT;
transmitting instructions to the programmable tester module for executing a program flow, wherein the program flow comprises a sequence of tests for testing the at least one DUT; and
receiving results from the programmable tester module associated with running the sequence of tests in the program flow on the at least one DUT.

2. The method of claim 1, further comprising:
consolidating results received from the programmable tester module; and
analyzing the results received from the programmable tester module.

3. The method of claim 1, further comprising rendering a graphical user interface (GUI) for entering login information to access the configuration file on the remote computer.

4. The method of claim 1, wherein the accessing the configuration file is performed through a website.

5. The method of claim 1, wherein the configuring is performed through the network from the remote computer.

6. The method of claim 1, wherein the accessing the configuration file on the remote computer is controlled based on criteria associated with a customer.

7. The method of claim 1 further comprising uploading the results received from the programmable tester module to the remote computer through the network.

8. A method for performing tests using automated test equipment (ATE), said method comprising:
obtaining a plurality of protocol selections for programming a plurality of programmable tester modules;
accessing configuration files associated with the plurality of protocol selections from a remote computer through a network;
configuring a plurality of programmable tester modules with communication protocols for application to a plurality of devices under test (DUTs) using the respective configuration files, wherein the plurality of programmable tester modules are communicatively coupled to the plurality of DUTs;
transmitting instructions to the plurality of programmable tester modules for executing tests on the plurality of DUTs; and
receiving results from the plurality of programmable tester modules associated with running the tests on the plurality of DUTs.

9. The method of claim 8 further comprising:
consolidating results received from the plurality of programmable tester modules; and
analyzing the results received from the plurality of programmable tester modules.

10. The method of claim 9 wherein the analyzing comprises analyzing the associated yield for the plurality of DUTs under test.

11. The method of claim 9 further comprising uploading the results from the plurality of programmable tester modules to the remote computer through the network.

12. The method of claim 11 further comprising diagnosing problems associated with the plurality of programmable tester modules and the plurality of DUTs using the results from the plurality of programmable tester modules uploaded to the remote computer.

13. The method of claim 8, further comprising rendering a graphical user interface (GUI) for entering login information to access the configuration files on the remote computer.

14. A system for performing an automated test, said system comprising:
a system controller communicatively coupled to at least one programmable tester module, wherein the system controller comprises:
memory comprising a test application stored therein;
a test interface to connect to the at least one programmable tester module; and
a processor coupled to the memory and the test interface, the processor being configured to operate in accordance with the test application to:
obtain a protocol selection for programming the at least one programmable tester module using a graphical user interface (GUI);
access a configuration file associated with a protocol from a remote computer through a network;
configure the at least one programmable tester module with a communication protocol for application to at least one device under test (DUT) using the configuration file, wherein the at least one programmable tester module is operable to be communicatively coupled to the at least one DUT;
transmit instructions to the at least one programmable tester module for executing a program flow, wherein the program flow comprises a sequence of tests for testing the at least one DUT; and
receive results from the programmable tester module associated with running the sequence of tests in the program flow on the at least one DUT.

15. The system of claim 14 wherein the processor is further configured to operate in accordance with the test application to:
consolidate results received from the programmable tester module; and
analyzing the results received from the programmable tester module.

16. The system of claim 14 wherein the processor is further configured to operate in accordance with the test application to implement a graphical user interface (GUI) for entering login information to access the configuration file on the remote computer.

17. The system of claim 14 wherein the configuration file is accessed through a website.

18. The system of claim 14 wherein the processor is further configured to operate in accordance with the test application to upload the results received from the programmable tester module to the remote computer through the network.

19. A method for performing tests using automated test equipment (ATE), said method comprising:
receiving a protocol selection for programming a programmable tester modules from a remote client computer;
accessing a configuration file associated with the protocol selection;
transmitting the configuration file associated with the protocol selection to the remote client computer;
configuring a programmable tester module remotely with a communication protocol for application to at least one device under test (DUT) using the configuration file, wherein the programmable tester module is communicatively coupled to the at least one DUT;
transmitting instructions to the programmable tester module for executing a program flow, wherein the program flow comprises a sequence of tests for testing the at least one DUT; and
receiving results from the remote client computer associated with running the sequence of tests in the program flow on the at least one DUT.
